(19) United States
(12) Patent Application Publication
(10) Pub. No.: US 2022/0326580 A1
(43) Pub. Date: Oct. 13, 2022

(54) CAPACITOR STRUCTURE, TRANSISTOR ARRAY SUBSTRATE, TRANSISTOR ARRAY SUBSTRATE PRODUCTION METHOD, LIQUID CRYSTAL DISPLAY DEVICE, AND ELECTRONIC APPARATUS

(71) Applicant: SONY GROUP CORPORATION, TOKYO (JP)

(72) Inventor: SHINTARO NAKANO, TOKYO (JP)

(21) Appl. No.: 17/753,595

(22) PCT Filed: Jul. 18, 2020
(86) PCT No.: PCT/JP2020/027977

§ 371 Date: Mar. 9, 2022

(30) Foreign Application Priority Data
Sep. 17, 2019 (JP) 2019-168095

(51) Int. Cl. G02F 1/1362; G02F 1/1368; G02F 1/1333; G02F 1/1339; H01L 27/12

(52) U.S. Cl. CPC G02F 1/136213; G02F 1/1368; G02F 1/136286; G02F 1/133345; G02F 1/136209; G02F 1/1339; H01L 27/1255; H01L 27/1259; G02F 2202/16

(57) ABSTRACT

A transistor array substrate includes a capacitor structure and a transistor formed on a support substrate. The capacitor structure includes a relay electrode, a lower electrode that has a bottom surface disposed on the relay electrode and has a wall surface extending obliquely with respect to the bottom surface, a dielectric film that is formed on the lower electrode, and an upper electrode that is formed on the dielectric film. The dielectric film and the upper electrode are formed in accordance with the lower electrode. A conductive material is embedded in a recess portion in the upper electrode.

### TECHNICAL FIELD

The present disclosure relates to a capacitor structure, a transistor array substrate, a transistor array substrate production method, a liquid crystal display device, and an electronic apparatus.

### BACKGROUND ART

A liquid crystal display device having a structure in which a liquid crystal material layer is disposed between a transistor array substrate where transistors serving as switching elements are arranged in a matrix form and a counter substrate where a counter electrode is provided has been known. In such a liquid crystal display device, pixels are operated so as to serve as light shutters (light valves) to display an image. In recent years, not only improvement of definition but also improvement of luminance has been demanded in liquid crystal display devices. Therefore, efforts for improving the aperture ratio of a pixel by designing finer patterns are being made.

In an active matrix type liquid crystal display device, voltage is applied to a pixel via a switching element, and then, the switching element enters a non-conductive state. Subsequently, the voltage is held by a capacitor structure (capacitor section) of the pixel, whereby display is performed. However, reduction of a wire width, due to a finer pattern, leads to reduction of an area where the capacitor structure can be placed. This affects the held voltage. To this end, in some configurations, a plurality of capacitor structures in each of which a dielectric is disposed between electrodes is layered, and, in other configurations, even a side wall functions as a capacitance (for example, see PTL 1).

### CITATION LIST

### Patent Literature

### [PTL 1]

Japanese Patent Laid-Open No. 2016-33680

### SUMMARY

### Technical Problem

Various kinds of voltages are applied to a capacitor structure through a contact. In a capacitor structure in which even a side wall functions as a capacitance, it is normal to connect a contact to an electrode that is led out of the capacitor structure. In such a configuration, however, an area required for connection does not function as a capacitance. As a result, the efficiency of a plan layout is deteriorated. For this reason, a capacitor structure, which can be connected to a contact without involving deterioration of the efficiency, has been desired.

Therefore, an object of the present disclosure is to provide a capacitor structure which can be connected to a contact without involving deterioration of the efficiency of a plan layout, a transistor array substrate including the capacitor structure, a production method for the transistor array substrate, a liquid crystal display device equipped with the transistor array substrate, and an electronic apparatus equipped with the liquid crystal display device.

### Solution to Problem

In order to achieve the above object, a capacitor structure according to the present disclosure includes

a relay electrode,

a lower electrode that has a bottom surface disposed on the relay electrode and has a wall surface extending obliquely with respect to the bottom surface,

a dielectric film that is formed on the lower electrode, and

an upper electrode that is formed on the dielectric film, in which

the dielectric film and the upper electrode are formed in accordance with the lower electrode, and

a conductive material is embedded in a recess portion in the upper electrode.

In order to achieve the above object, a transistor array substrate according to the present disclosure includes

a capacitor structure and a transistor formed on a support substrate, in which

the capacitor structure includes
a relay electrode,
a lower electrode that has a bottom surface disposed on the relay electrode and has a wall surface extending obliquely with respect to the bottom surface,
a dielectric film that is formed on the lower electrode, and
an upper electrode that is formed on the dielectric film,

the dielectric film and the upper electrode are formed in accordance with the lower electrode, and

a conductive material is embedded in a recess portion in the upper electrode.

In order to achieve the above object, a transistor array substrate production method according to a first aspect of the present disclosure including a step of forming a capacitor structure on a support substrate, includes

step of providing a relay electrode on an insulating layer, forming an interlayer insulating film over an entire surface, and then, forming an opening portion in the interlayer insulating film in such a way that the opening portion has a bottom portion from which the relay electrode is exposed, and has a wall surface extending obliquely with respect to the bottom portion,

a step of subsequently forming a first conductive material layer to form a lower electrode, an insulating material layer to form a dielectric film, and a second conductive material layer to form an upper electrode sequentially over an entire surface including an inner side of the opening portion,

a step of subsequently forming a third conductive material layer over an entire surface including an area above the upper electrode, and

a step of subsequently performing, on an entire surface, a flattening process so as to expose the interlayer insulating film.

In order to achieve the above object, a transistor array substrate production method according to a second aspect of the present disclosure including a step of forming a capacitor structure on a support substrate, includes

a step of providing a relay electrode on an insulating layer, forming an interlayer insulating film over an entire surface, and then, forming an opening portion in the interlayer insulating film in such a way that the opening portion has a bottom portion from which the relay electrode is exposed, and has a wall surface extending obliquely with respect to the bottom portion,

a step of subsequently forming a first conductive material layer to form a lower electrode, over an entire surface including an inner side of the opening portion;

a step of subsequently performing, on an entire surface, a flattening process so as to expose the interlayer insulating film, and

a step of subsequently forming a dielectric film that coats an end surface of the lower electrode and an interlayer insulating film region around the end surface of the lower electrode, an upper electrode that is disposed on the dielectric film, and a conductive material that is embedded in a recess portion in the upper electrode.

In order to achieve the above object, a liquid crystal display device according to the present disclosure includes

a transistor array substrate,

a counter substrate that is opposed to the transistor array substrate, and

a liquid crystal material layer that is sealed between the transistor array substrate and the counter substrate, in which

the transistor array substrate includes a capacitor structure and a transistor formed on a support substrate,

the capacitor structure includes
a relay electrode,
a lower electrode that has a bottom surface disposed on the relay electrode and has a wall surface extending obliquely with respect to the bottom surface,
a dielectric film that is formed on the lower electrode, and
an upper electrode that is formed on the dielectric film,

the dielectric film and the upper electrode are formed in accordance with the lower electrode, and

a conductive material is embedded in a recess portion in the upper electrode.

In order to achieve the above object, an electronic apparatus according to the present disclosure is equipped with a liquid crystal display device, and the liquid crystal display device includes

a transistor array substrate,

a counter substrate that is opposed to the transistor array substrate, and

a liquid crystal material layer that is sealed between the transistor array substrate and the counter substrate, in which

the transistor array substrate includes a capacitor structure and a transistor formed on a support substrate,

the capacitor structure includes
a relay electrode,
a lower electrode that has a bottom surface disposed on the relay electrode and has a wall surface extending obliquely with respect to the bottom surface,
a dielectric film that is formed on the lower electrode, and
an upper electrode that is formed on the dielectric film,

the dielectric film and the upper electrode are formed in accordance with the lower electrode, and

a conductive material is embedded in a recess portion in the upper electrode.

### BRIEF DESCRIPTION OF DRAWINGS

FIG. 1 is a schematic diagram for explaining a liquid crystal display device using a transistor array substrate according to the present disclosure.

FIG. 2A is a schematic cross-sectional view of a basic configuration of the liquid crystal display device. FIG. 2B is a schematic circuit diagram of a pixel in the liquid crystal display device.

FIG. 3 is a schematic partial plan view of the transistor array substrate according to the present disclosure.

FIGS. 4A and 4B are diagrams for explaining a cross-sectional structure of the transistor array substrate. FIG. 4A is a schematic partial plan view including an area between pixel electrodes in the transistor array substrate. FIG. 4B is a schematic cross-sectional view of a part taken along A-A in FIG. 4A.

FIGS. 5A and 5B are diagrams for explaining a cross-sectional structure of the transistor array substrate. FIG. 5A is a schematic partial plan view including an area between pixel electrodes in the transistor array substrate. FIG. 5B is a schematic cross-sectional view of a part taken along B-B in FIG. 5A.

FIGS. 6A and 6B are diagrams for explaining a cross-sectional structure of the transistor array substrate. FIG. 6A is a schematic partial plan view including an area between pixel electrodes in the transistor array substrate. FIG. 6B is a schematic cross-sectional view of a part taken along C-C in FIG. 6A.

FIG. 7 is a schematic partial plan view for explaining a transistor array substrate production method.

FIG. 8 is a schematic partial plan view for explaining the transistor array substrate production method, successively to FIG. 7.

FIG. 9 is a schematic partial plan view for explaining the transistor array substrate production method, successively to FIG. 8.

FIGS. 10A, 10B, and 10C are schematic partial cross-sectional views for explaining the transistor array substrate production method.

FIG. 11 is a schematic partial plan view for explaining the transistor array substrate production method, successively to FIG. 9.

FIG. 12 is a schematic partial plan view for explaining the transistor array substrate production method, successively to FIG. 11.

FIGS. 13A, 13B, and 13C are schematic partial cross-sectional views for explaining the transistor array substrate production method.

FIG. 14 is a schematic partial plan view for explaining the transistor array substrate production method, successively to FIG. 12.

FIGS. 15A, 15B, and 15C are schematic partial cross-sectional views for explaining the transistor array substrate production method.

FIG. 16 is a schematic partial plan view for explaining the transistor array substrate production method, successively to FIG. 14.

FIG. 17 is a schematic partial plan view for explaining the transistor array substrate production method, successively to FIG. 16.

FIG. 18 is a schematic partial plan view for explaining the transistor array substrate production method, successively to FIG. 17.

FIG. 19 is a schematic partial plan view for explaining the transistor array substrate production method, successively to FIG. 18.

FIGS. 20A, 20B, and 20C are schematic partial cross-sectional views for explaining a transistor array substrate production method according to a first modification.

FIGS. 21A, 21B, and 21C are schematic partial cross-sectional views for explaining the transistor array substrate production method according to the first modification, successively to FIG. 20C.

FIGS. 22A, 22B, and 22C are schematic partial cross-sectional views for explaining the transistor array substrate production method according to the first modification, successively to FIG. 21C.

FIGS. 23A, 23B, and 23C are schematic partial cross-sectional views for explaining a transistor array substrate production method according to a second modification.

FIGS. 24A, 24B, and 24C are schematic partial cross-sectional views for explaining the transistor array substrate production method according to the second modification, successively to FIG. 23C.

FIGS. 25A and 25B are diagrams for explaining a cross-sectional structure of a transistor array substrate according to a third modification. FIG. 25A is a schematic partial plan view including an area between pixel electrodes in the transistor array substrate. FIG. 25B is a schematic cross-sectional view of a part taken along A-A in FIG. 25A.

FIGS. 26A and 26B are diagrams for explaining a cross-sectional structure of a transistor array substrate according to a fourth modification. FIG. 26A is a schematic partial plan view including an area between pixel electrodes in the transistor array substrate. FIG. 26B is a schematic cross-sectional view of a part taken along A-A in FIG. 26A.

FIGS. 27A and 27B are diagrams for explaining the cross-sectional structure of a transistor array substrate according to a fifth modification. FIG. 27A is a schematic partial plan view including an area between pixel electrodes in the transistor array substrate. FIG. 27B is a schematic cross-sectional view of a part taken along B-B in FIG. 27A.

FIGS. 28A and 28B are diagrams for explaining a cross-sectional structure of the transistor array substrate according to the fifth modification, successively to FIG. 27B. FIG. 28A is a schematic partial plan view including an area between pixel electrodes in the transistor array substrate. FIG. 28B is a schematic cross-sectional view of a part taken along C-C in FIG. 28A.

FIGS. 29A and 29B are diagrams for explaining the cross-sectional structure of a transistor array substrate according to a sixth modification. FIG. 29A is a schematic partial plan view including an area between pixel electrodes in the transistor array substrate. FIG. 29B is a schematic cross-sectional view of a part taken along A-A in FIG. 29A.

FIGS. 30A and 30B are diagrams for explaining the cross-sectional structure of the transistor array substrate according to the sixth modification, successively to FIG. 29B. FIG. 30A is a schematic partial plan view including an area between pixel electrodes in the transistor array substrate. FIG. 30B is a schematic cross-sectional view of a part taken along B-B in FIG. 30A.

FIGS. 31A and 31B are diagrams for explaining the cross-sectional structure of the transistor array substrate according to the sixth modification, successively to FIG. 30B. FIG. 31A is a schematic partial plan view including an area between pixel electrodes in the transistor array substrate. FIG. 31B is a schematic cross-sectional view of a part taken along C-C in FIG. 31A.

FIGS. 32A and 32B are diagrams for explaining a cross-sectional structure of a transistor array substrate according to a seventh modification. FIG. 32A is a schematic partial plan view including an area between pixel electrodes in the transistor array substrate. FIG. 32B is a schematic cross-sectional view of a part taken along A-A in FIG. 32A.

FIGS. 33A and 33B are diagrams for explaining the cross-sectional structure of the transistor array substrate according to the seventh modification, successively to FIG. 32B. FIG. 33A is a schematic partial plan view including an area between pixel electrodes in the transistor array substrate. FIG. 33B is a schematic cross-sectional view of a part taken along B-B in FIG. 33A.

FIGS. 34A and 34B are diagrams for explaining the cross-sectional structure of the transistor array substrate according to the seventh modification, successively to FIG. 33B. FIG. 34A is a schematic partial plan view including an area between pixel electrodes in the transistor array substrate. FIG. 34B is a schematic cross-sectional view of a part taken along C-C in FIG. 34A.

FIG. 35 is a conceptual diagram of a projection-type display device.

FIG. 36 is a diagram illustrating an external appearance of a lens interchangeable single-lens reflex type digital still camera. FIG. 36A is a front view of the camera. FIG. 36B is a rear view of the camera.

FIG. 37 is a diagram illustrating an external appearance of a head mounted display.

FIG. 38 is a diagram illustrating an external appearance of a see-through head mounted display.

FIG. 39 is a block diagram depicting an example of schematic configuration of a vehicle control system.

FIG. 40 is a diagram of assistance in explaining an example of installation positions of an outside-vehicle information detecting section and an imaging section.

### DESCRIPTION OF EMBODIMENTS

Hereinafter, the present disclosure will be explained on the basis of embodiments with reference to the drawings. The present disclosure is not limited to these embodiments. Numerical values and materials in the embodiments are examples. In the following explanation, the same element or an element having the same function is denoted by the same reference sign, and an overlapping explanation thereof will be omitted. It is to be noted that the explanation will be given in accordance with the following order.

1. General Explanation Of Capacitor Structure, Transistor Array Substrate, Transistor Array Substrate Production Method, Liquid Crystal Display Device, and Electronic Apparatus, According to Present Disclosure

2. First Embodiment

3. First Modification

4. Second Modification

5. Third Modification

6. Fourth Modification

7. Fifth Modification

8. Sixth Modification

9. Seventh Modification

10. Explanation Of Electronic Apparatus, and Others

### General Explanation Of Capacitor Structure, Transistor Array Substrate, Transistor Array Substrate Production Method, Liquid Crystal Display Device, and Electronic Apparatus, According to Present Disclosure

In the following explanation, a transistor array substrate according to the present disclosure, a transistor array substrate obtained by a transistor array substrate production method according to the present disclosure, a transistor array substrate that is used in a liquid crystal display device according to the present disclosure, and a transistor array substrate that is used in a liquid crystal display device included in an electronic apparatus according to the present disclosure, are all simply referred to as [transistor array substrate according to the present disclosure].

As previously explained, a capacitor structure according to the present disclosure, or a capacitor structure that is used in a transistor array substrate according to the present disclosure (hereinafter, these are simply referred to as [capacitor structure according to the present disclosure]) includes

a relay electrode,

a lower electrode that has a bottom surface disposed on the relay electrode and has a wall surface extending obliquely with respect to the bottom surface,

a dielectric film that is formed on the lower electrode, and

an upper electrode that is formed on the dielectric film, in which

the dielectric film and the upper electrode are formed in accordance with the lower electrode, and

a conductive material is embedded in a recess portion in the upper electrode.

In the transistor array substrate according to the present disclosure, a wiring layer may be formed above the capacitor structure, a contact between the upper electrode of the capacitor structure and the wiring layer may be formed so as to be in contact with the conductive material that is embedded in the recess portion in the upper electrode. With this configuration, an area required for connection is included in a region where the capacitor structure is disposed. Accordingly, connection to the contact can be established without involving deterioration of the efficiency of a plan layout.

In the transistor array substrate according to the present disclosure including the aforementioned preferable configuration, the lower electrode, the dielectric film, and the upper electrode may be formed in an opening portion that is disposed in an interlayer insulating film, and an upper surface of the capacitor structure can be flattened in accordance with an upper surface of the interlayer insulating film.

In this case, respective end surfaces, on the upper surface of the capacitor structure, of the lower electrode, the dielectric film, and the upper electrode can be flattened in accordance with the upper surface of the interlayer insulating film. Alternatively, the end surface, on the upper surface of the capacitor structure of the dielectric film, can be inwardly recessed from the respective end surfaces of the lower electrode and the upper electrode. Compared to the former configuration, the latter configuration further requires a step of processing the dielectric film, but has an advantageous effect that leakage in the end surfaces can be further reduced.

Alternatively, in the transistor array substrate according to the present disclosure including the aforementioned preferable configuration, the lower electrode can be formed in an opening portion that is disposed in the interlayer insulating film, the end surface of the lower electrode can be flattened in accordance with the upper surface of the interlayer insulating film, and the dielectric film can be formed so as to coat the end surface of the lower electrode and the interlayer insulating film region around the end surface of the lower electrode. With this configuration, the end surface of the lower electrode is coated with the dielectric film. Accordingly, leakage between the lower electrode and the upper electrode can be effectively reduced.

In the transistor array substrate according to the present disclosure including the aforementioned preferable configuration, the lower electrode can have a plurality of bottom surfaces. With this configuration, the area of the wall surfaces extending obliquely from the bottom surfaces can be increased. Accordingly, the capacitance value of the capacitor structure can be further enhanced.

In the transistor array substrate according to the present disclosure including the aforementioned preferable configuration, the capacitor structure can be disposed between the transistor and the wiring layer. Alternatively, the transistor array substrate can have a plurality of wiring layers, and the capacitor structure can be disposed between the wiring layers.

The transistor array substrate, according to the present disclosure including the aforementioned preferable configuration, can further include a pixel electrode to which a pixel voltage held by the capacitor structure is applied.

In a case where the transistor array substrate is used for a transmission type liquid crystal display device, the pixel electrode can be formed by a transparent conductive material such as indium tin oxide (ITO) or indium zinc oxide (IZO). In a case where the transistor array substrate is used for a reflection type liquid crystal display device, the pixel electrode can be formed by a metal material such as aluminum (Al), silver (Ag), or an alloy thereof. It is to be noted that the pixel electrode can be formed by layering the above transparent conductive material and the above metal material.

In the transistor array substrate according to the present disclosure including the aforementioned preferable configurations, the transistor can be disposed above a scan line that is disposed on the support substrate, and the periphery of the transistor may be enclosed with a wall-shaped lateral light shielding film extending in a direction that is normal to the support substrate. In this case, the lateral light shielding film can be formed along an edge of the scan line.

In an active matrix type liquid crystal display device, voltage is applied to a pixel via a switching element, and then, the switching element enters a non-conductive state. Subsequently, the voltage is held by a capacitor structure in the pixel, whereby display is performed. Therefore, if incident light causes a flow of a leakage current through the switching element which should be in a non-conductive state, the voltage fluctuates. This results in deterioration of the display quality. The leakage can be reduced by shielding the transistor from light in the aforementioned manner.

As previously explained, a transistor array substrate production method according to a first aspect of the present disclosure, includes

a step of providing a relay electrode on an insulating layer, forming an interlayer insulating film over an entire surface, and then, forming an opening portion in the interlayer insulating film in such a way that the opening portion has a bottom portion from which the relay electrode is exposed, and has a wall surface extending obliquely with respect to the bottom portion,

a step of subsequently forming a first conductive material layer to form a lower electrode, an insulating material layer to form a dielectric film, and a second conductive material layer to form an upper electrode sequentially over an entire surface including an inner side of the opening portion,

a step of subsequently forming a third conductive material layer over an entire surface including an area above the upper electrode, and

a step of subsequently performing, on an entire surface, a flattening process so as to expose the interlayer insulating film.

In this case, after the flattening process is performed, a step of etching an end of the dielectric film can be further included. As a result of this step, an end surface, on the upper surface of the capacitor structure of the dielectric film, is inwardly recessed from respective end surfaces of the lower electrode and the upper electrode. Accordingly, leakage in the end surfaces can be further reduced.

In the transistor array substrate production method according to the first aspect of the present disclosure having the aforementioned preferable configuration, a contact between the upper electrode of the capacitor structure and a wiring layer disposed above the capacitor structure can be formed so as to be in contact with a conductive material that is embedded in a recess portion in the upper electrode.

As previously explained, the transistor array substrate production method according to a second aspect of the present disclosure, includes

a step of providing a relay electrode on an insulating layer, forming an interlayer insulating film over an entire surface, and then, forming an opening portion in the interlayer insulating film in such a way that the opening portion has a bottom portion from which the relay electrode is exposed, and has a wall surface extending obliquely with respect to the bottom portion,

a step of subsequently forming a first conductive material layer to form a lower electrode, an insulating material layer to form a dielectric film, and a second conductive material layer to form an upper electrode sequentially over an entire surface including an inner side of the opening portion,

a step of subsequently forming a third conductive material layer over an entire surface including an area above the upper electrode, and

a step of subsequently performing, on an entire surface, a flattening process so as to expose the interlayer insulating film.

Also in the transistor array substrate production method according to the second aspect of the present disclosure, a contact between the upper electrode of the capacitor structure and a wiring layer disposed above the capacitor structure may be formed so as to be in contact with a conductive material that is embedded in a recess portion in the upper electrode.

As previously explained, a liquid crystal display device according to the present disclosure, or a liquid crystal display device that is used for an electronic apparatus according to the present disclosure (hereinafter, these are simply referred to as [liquid crystal display device according to the present disclosure]) includes

a transistor array substrate,

a counter substrate that is opposed to the transistor array substrate, and

a liquid crystal material layer that is sealed between the transistor array substrate and the counter substrate.

A substrate made from a transparent material such as a glass material can be used as the counter substrate. On the counter substrate, a counter electrode can be formed by a transparent conductive material such as indium tin oxide (ITO) or indium zinc oxide (IZO). The counter electrode functions as a common electrode for pixels in the liquid crystal display device.

A substrate made from a transparent material such as a glass material, or a substrate made from a semiconductor material such as silicon can be used as the transistor array substrate. The transistor forming a switching element can be obtained by forming and processing a semiconductor material layer or the like on a substrate, for example.

Materials for wires, electrodes, and contacts are not limited to a particular material. Metal materials including aluminum (Al), an aluminum alloy such as Al—Cu or Al—Si, tungsten (W), and a tungsten alloy such as tungsten silicide (WSi), for example, can be used therefor.

Materials for the insulating layer and insulating film are not limited to a particular material. Inorganic materials including silicon oxide, silicon oxynitride, and silicon nitride, or organic materials including polyimide can be used therefor.

Methods for forming the semiconductor material layer, the wires, the electrodes, the insulating layer, the insulating film, etc. are not limited to a particular method. A well-known film forming method can be used as long as the method does not pose any problem in carrying out the present disclosure. The similar method applies to patterning methods therefor.

The liquid crystal display device may be configured to display a monochrome image, or may be configured to display a color image. Examples of a pixel value in the liquid crystal display device can include some image resolution examples including U-XGA (1600, 1200), HD-TV (1920, 1080), and Q-XGA (2048, 1536), (3840, 2160), (7680, 4320). However, the pixel value is not limited to these values.

In addition, examples of the electronic apparatus equipped with the liquid crystal display device according to the present disclosure can include a direct viewing type display apparatus, a projection type display apparatus, and any other types of electronic apparatuses having an image display function.

The various conditions which are explained in the present description may be strictly satisfied, or may be substantially satisfied. Design or production variations are allowed to be made. Moreover, the drawings which are used in the following explanation are schematic ones, and thus do not indicate any actual dimension or the actual ratio thereof.

### First Embodiment

The first embodiment relates to a capacitor structure, a transistor array substrate, a transistor array substrate production method, a liquid crystal display device, and an electronic apparatus according to the present disclosure.

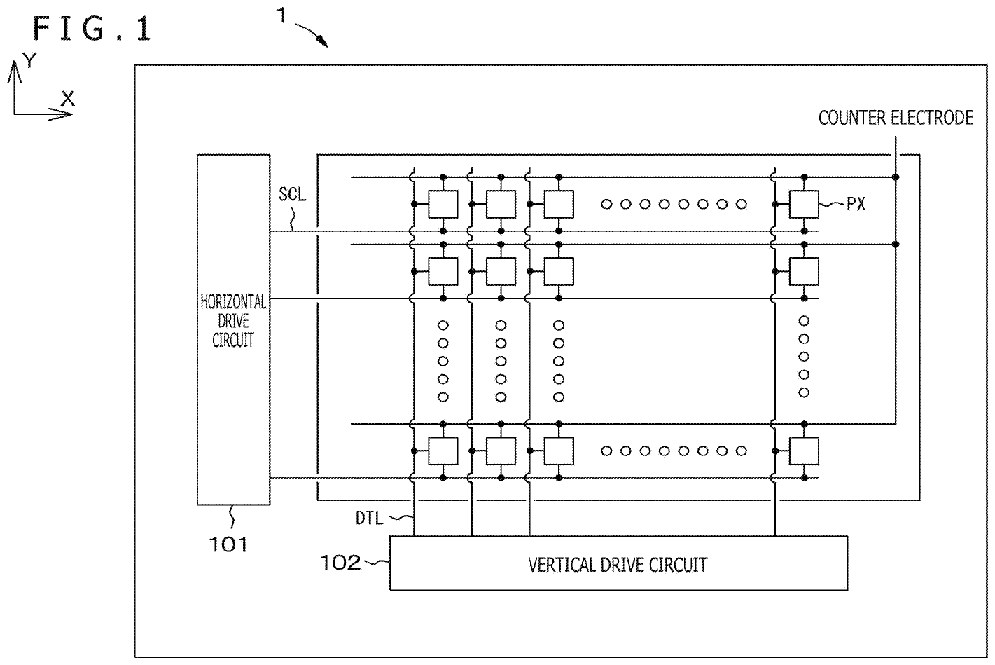

FIG. 1 is a schematic diagram for explaining a liquid crystal display device using a transistor array substrate according to the first embodiment of the present disclosure.

The liquid crystal display device according to the first embodiment is an active matrix type liquid crystal display device. As illustrated in FIG. 1, the liquid crystal display device 1 includes pixels PX that are arranged in a matrix form, and various circuits which are a horizontal drive circuit 101 and a vertical drive circuit 102 for driving the pixels PX. Reference sign SCL denotes a scan line for scanning the pixels PX. Reference sign DTL denotes a signal line for supplying various types of voltage to the pixels PX. For example, M pixels PX are arranged in the horizontal direction while N pixels PX are arranged in the vertical direction so that the total of M×N pixels PX are arranged in a matrix form. A counter electrode in FIG. 1 is provided as a common electrode for liquid crystal cells. It is to be noted that, in FIG. 1, the horizontal drive circuit 101 is disposed on one end side of the liquid crystal display device 1 while the vertical drive circuit 102 is disposed on another end side. However, this is just an example.

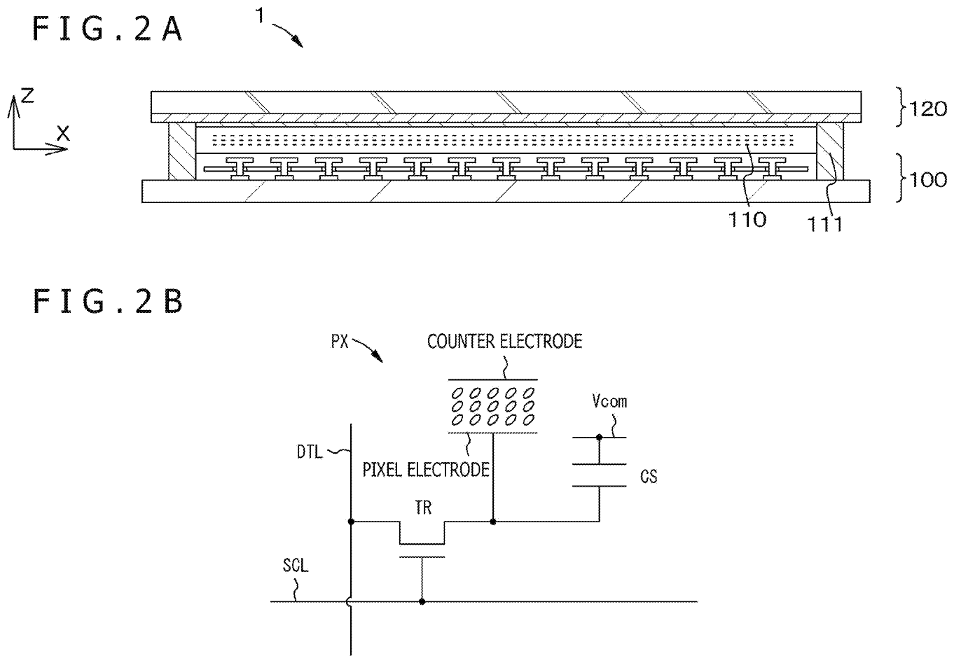

FIG. 2A is a schematic cross-sectional view for explaining a basic configuration of the liquid crystal display device. FIG. 2B is a schematic circuit diagram for explaining a pixel in the liquid crystal display device.

As illustrated in FIG. 2A, the liquid crystal display device 1 includes

a transistor array substrate 100,

a counter substrate 120 that is opposed to the transistor array substrate, and

a liquid crystal material layer 110 that is sealed between the transistor array substrate and the counter substrate. The transistor array substrate 100 and the counter substrate 120 are sealed by a seal section 111. The seal section 111 has an annular shape surrounding the liquid crystal material layer 110.

For example, the transistor array substrate 100 is formed by depositing components on a support substrate made from a glass material or the like, which will be explained later. The liquid crystal display device 1 is a transmission type liquid crystal display device.

A counter electrode made from a transparent conductive material such as ITO is provided on the counter substrate 120. More specifically, the counter substrate 120 includes a rectangular substrate that is made from transparent glass or the like, a counter electrode that is disposed on the liquid crystal material layer 110-side surface of the substrate, and an orientation film that is disposed on the counter electrode. In addition, a polarization plate, an orientation film, etc., are disposed, as appropriate, on the transistor array substrate 100 and the counter substrate 120. For convenience of illustration, the transistor array substrate 100 and the counter substrate 120 are simply illustrated in FIG. 2A.

As illustrated in FIG. 2B, a liquid cell constituting a pixel PX includes a pixel electrode that is disposed on the transistor array substrate 100, and a liquid crystal material layer and a counter electrode corresponding to the pixel electrode. In order to prevent deterioration of the liquid crystal material layer 110, common potentials V_{com} having a positive polarity and a negative polarity are alternately applied to the counter electrode during driving of the liquid crystal display device 1. It is to be noted that elements excluding the liquid crystal material layer and the counter electrode in the pixel PX are formed on the transistor array substrate 100 illustrated in FIG. 2A.

As is clear from the wire connection relationship in FIG. 2B, a pixel voltage supplied from a signal line DTL is applied to the pixel electrode via a transistor TR that is in a conductive state by a scan signal in the scan line SCL. Since the pixel electrode and one electrode of the capacitor structure CS are conducted, the pixel voltage is applied also to the one electrode of the capacitor structure CS. It is to be noted that a common potential V_{com} is applied to the other electrode of the capacitor structure CS. In this configuration, even after the transistor TR enters a non-conductive state, the voltage of the pixel electrode is held by the capacitance of the liquid crystal cell and the capacitor structure CS.

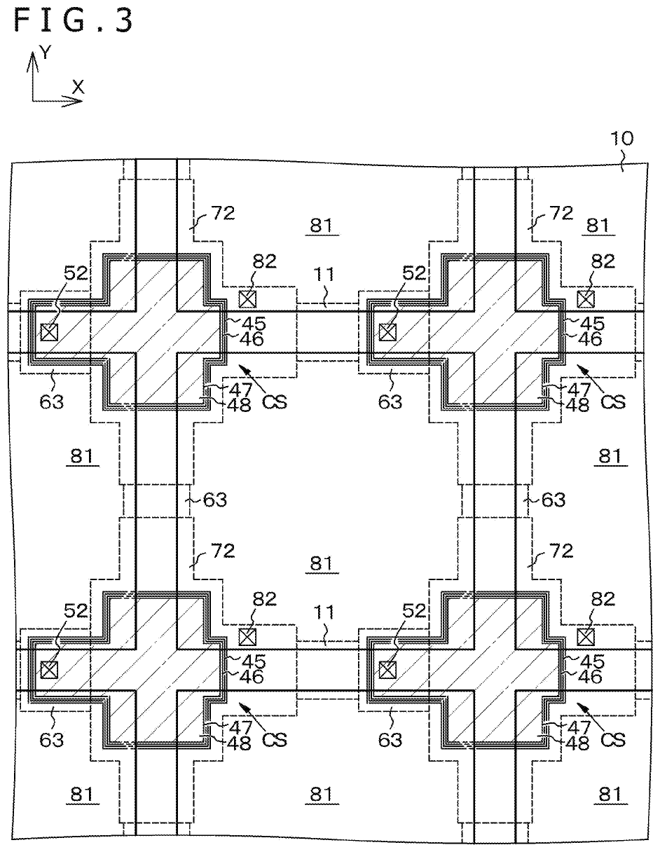

In the display device 1 according to the first embodiment, a transistor and a capacitor structure are formed on a support substrate forming the transistor array substrate 100. This will be explained later in detail with reference to FIGS. 3 to 19. The capacitor structure includes a relay electrode, a lower electrode that has a bottom surface disposed on the relay electrode and has a wall surface extending obliquely with respect to the bottom surface, a dielectric film that is formed on the lower electrode, and an upper electrode that is formed on the dielectric film. The dielectric film and the upper electrode are formed in accordance with the lower electrode. A conductive material is embedded in a recess portion in the upper electrode.

FIG. 3 is a schematic partial plan view for explaining a transistor array substrate according to the present disclosure.

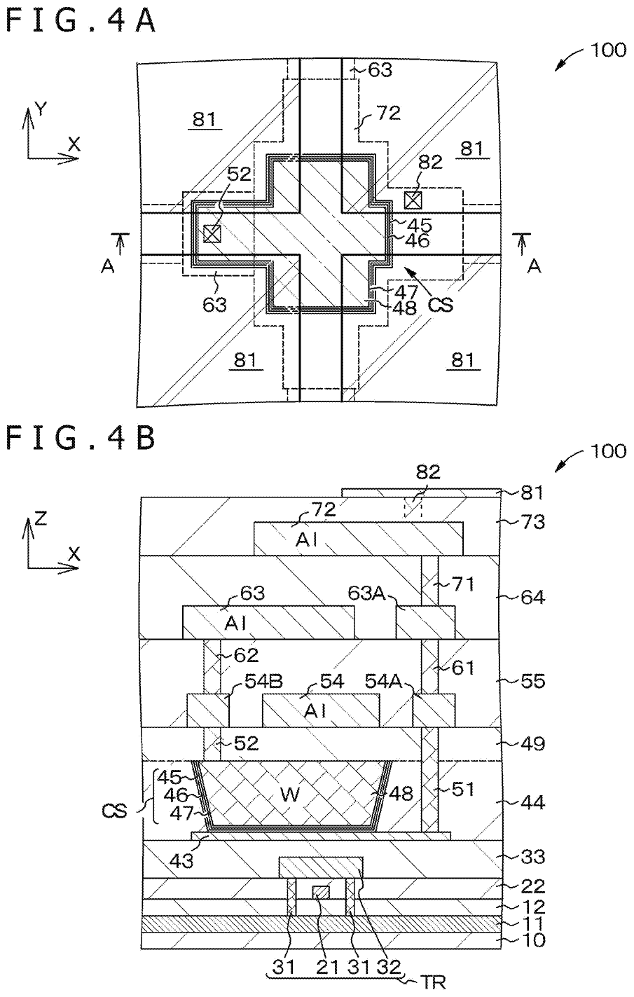

It is to be noted that, since many components are deposited, illustration of all the elements in the plan view leads to loss of readability. To this end, not all the elements are indicated in the plan view in FIG. 3. The arrangement relationship of the elements will be explained later in detail with reference to FIGS. 4 to 19.

Pixel electrodes 81 formed by dividing a transparent conductive material layer into matrixes, for example, are disposed on the transistor array substrate 100. Reference sign 82 denotes a contact to a lower layer side in each pixel electrode 81. A transistor TR (not illustrated) is formed between adjacent pixel electrodes 81. Reference signs 45, 46, 47, and 48 are components constituting the capacitor structure CS. Reference sign 45 denotes a lower electrode. Reference numeral 46 denotes a dielectric film that is disposed on the lower electrode 45. Reference sign 47 denotes an upper electrode that is disposed on the dielectric film 46. Reference sign 48 denotes a conductive material that is embedded in a recess portion in the upper electrode 47.

It is to be noted that, in FIG. 3, only end surfaces, on the upper surface of the capacitor structure CS of the lower electrode 45, the dielectric film 46, and the upper electrode 47, are illustrated. The plan shape of the conductive material 48 embedded in the recess portion in the upper electrode 47 is hatched.

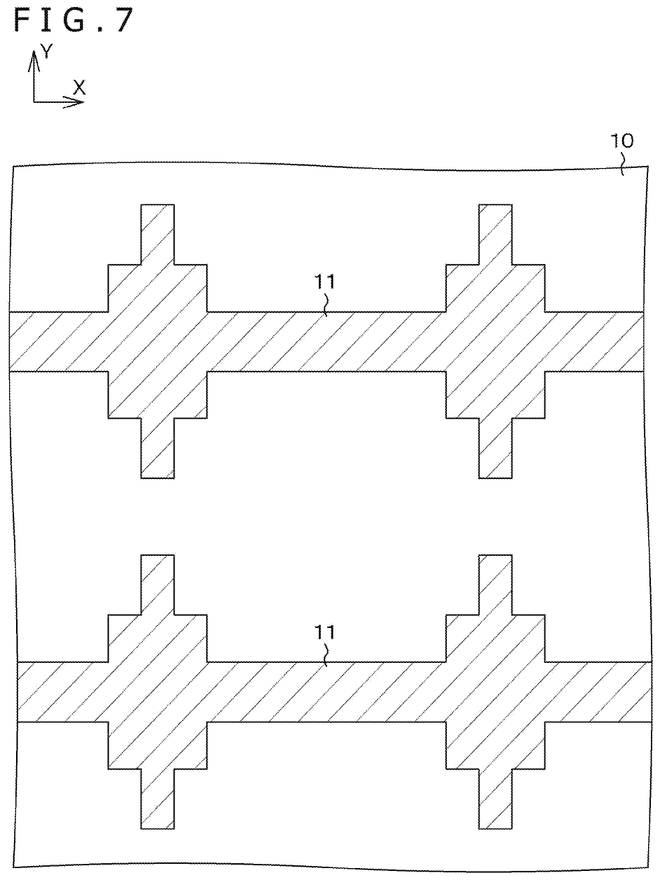

First, the arrangement relationship of the components will be explained with reference to FIGS. 4 to 6. It is to be noted that the plan shape of each component will be explained with reference to FIGS. 7 to 19, as appropriate, in order to explain a production method for the transistor array substrate.

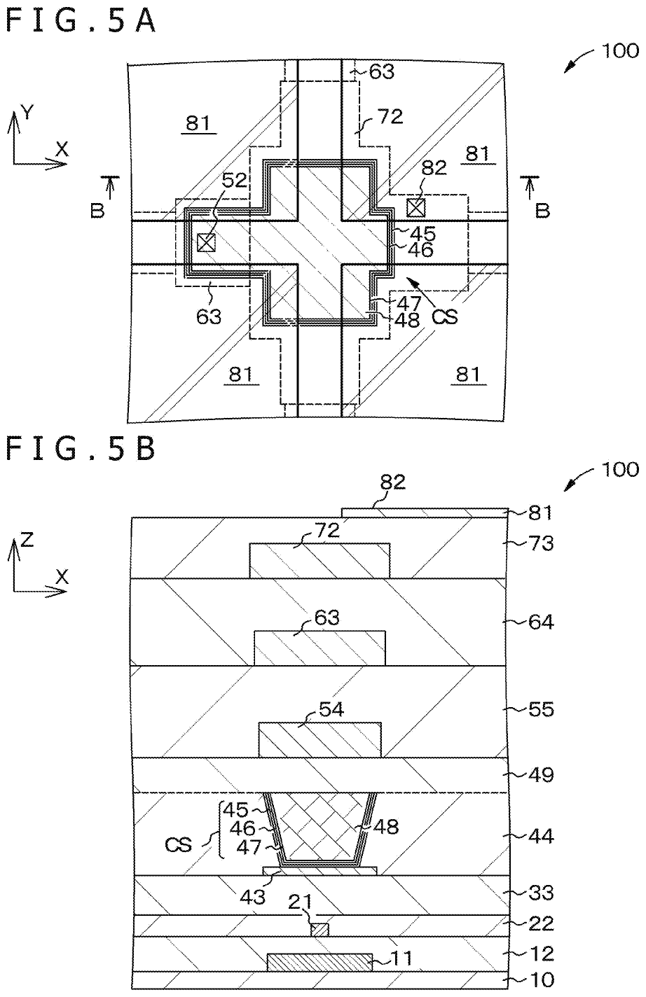

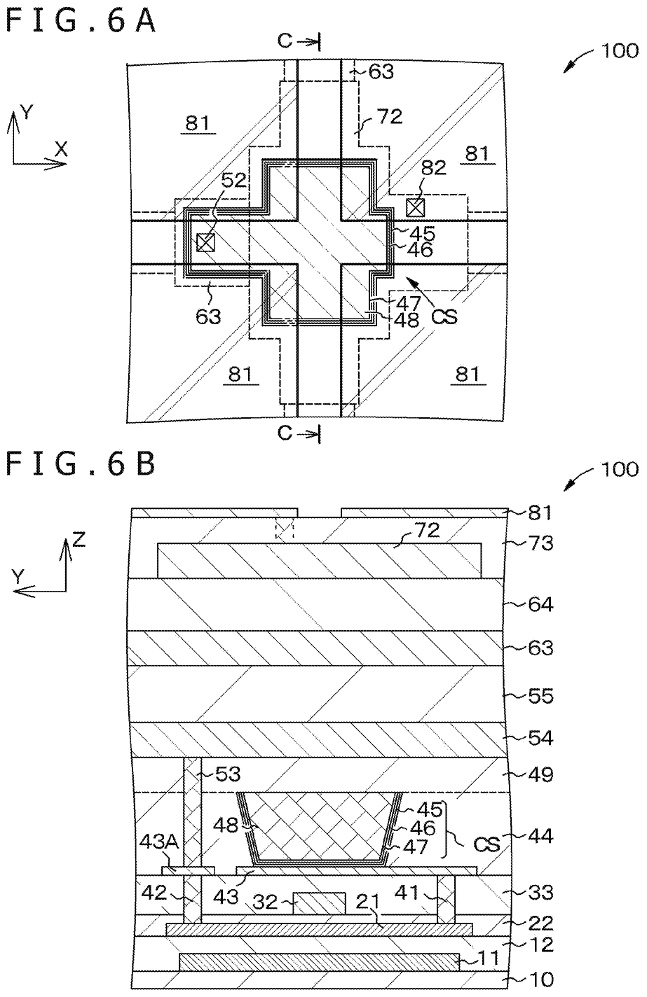

FIGS. 4A, 5A, and 6A are schematic partial plan views each including an area between pixel electrodes in the transistor array substrate. FIG. 4B is a schematic cross-sectional view of a part taken along A-A in FIG. 4A. FIG. 5B is a schematic cross-sectional view of a part taken along B-B in FIG. 5A. FIG. 6B is a schematic cross-sectional view of a part taken along C-C in FIG. 6A.

First, an explanation will be given with reference to FIGS. 4B, 5B, and 6B. A scan line 11 (corresponding to SCL in FIG. 1), which extends in an X direction in each drawing, is formed on a support substrate 10 constituting the transistor array substrate 100. A hatched part in FIG. 7 indicates a plan shape of the scan line 11.

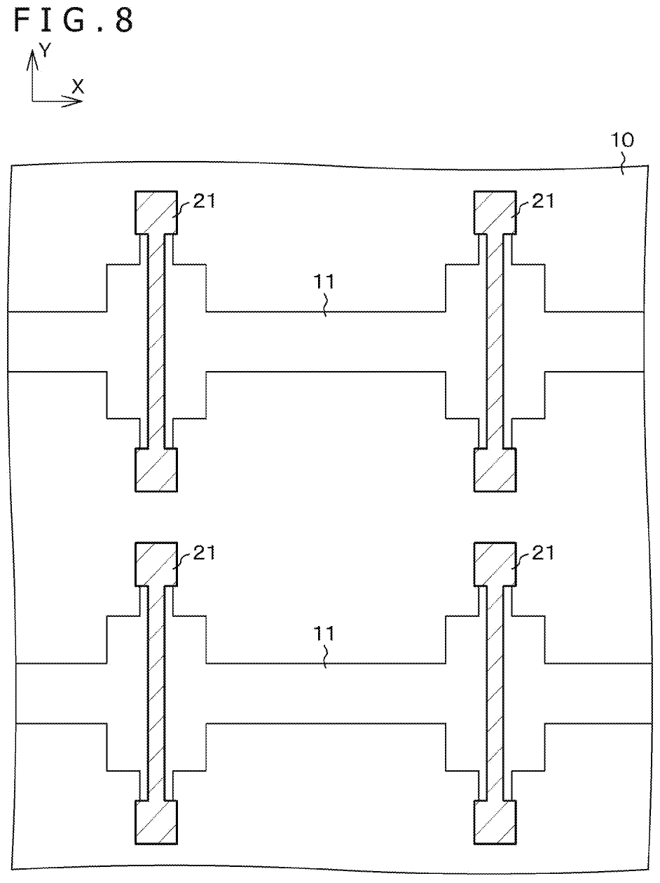

An insulating film 12 is formed over the entire surface including an area above the scan line 11. A semiconductor material layer 21 constituting the transistor TR is formed on the insulating film 12. The transistor TR includes a thin film transistor. A hatched part in FIG. 8 indicates a plan shape of the semiconductor material layer 21.

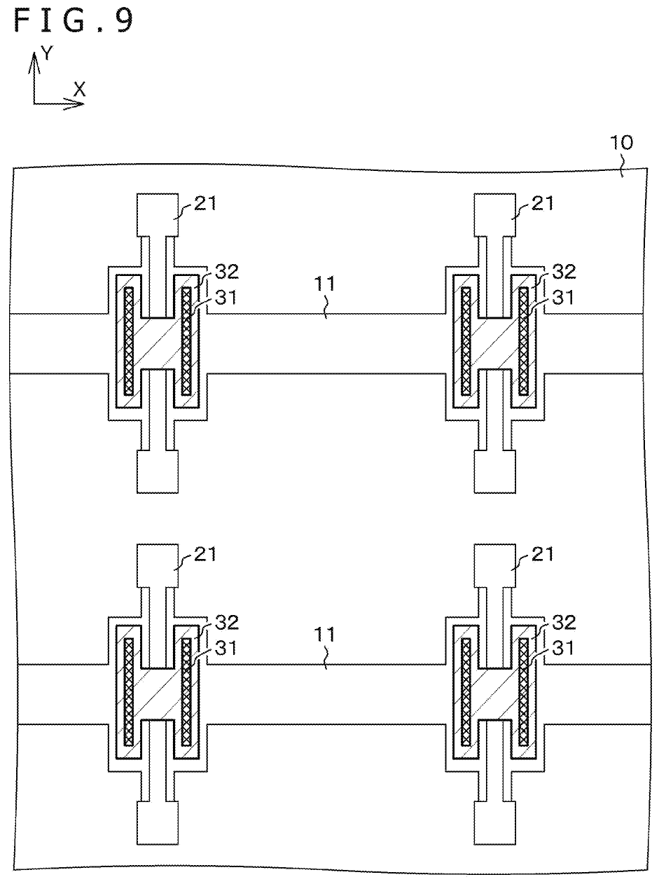

A gate insulating film 22 is formed over the entire surface including an area above the semiconductor material layer 21. A gate electrode 32 is formed on the gate insulating film 22. An opening portion from which the scan line 11 is exposed is provided on the gate insulating film 22. A contact 31 between the gate electrode 32 and the scan line 11 is formed in the opening portion. As illustrated in FIG. 4B, the semiconductor material layer 21 and the gate electrode 32 constitute the transistor TR. Hatched parts in FIG. 9 indicate plan shapes of the gate electrode 32 and the contact 31.

An insulating layer 33 is formed over the entire surface including an area above the gate electrode 32. The capacitor structure CS that is embedded in an interlayer insulating film 44 is formed on the insulating layer 33. The capacitor structure CS includes the relay electrode 43 that is formed on the insulating layer 33, a lower electrode 45 that has a bottom surface disposed on the relay electrode 43 and has a wall surface extending obliquely with respect to the bottom surface, the dielectric film 46 that is formed on the lower electrode 45, and the upper electrode 47 that is formed on the dielectric film 46. The dielectric film 46 and the upper electrode 47 are formed in accordance with the lower electrode 45. The conductive material 48 is embedded in a recess portion in the upper electrode 47.

Here, the conductive material that is used for the transistor array substrate 100 will be explained. In the transistor array substrate 100, tungsten (W) is used for the conductive material 48 that is embedded in the capacitor structure CS, as illustrated in FIG. 4B. In addition, a signal line 54, a common potential line 63, and a relay wire 72, which will be explained later, are formed by aluminum (Al). The relay electrode 43, the gate electrode 32, and the scan line 11 are formed by tungsten (W) or tungsten silicide (WSi), for example. The aforementioned conductive material or the like is selected and used for the lower electrode 45 and the upper electrode 47 of the capacitor structure CS, as appropriate.

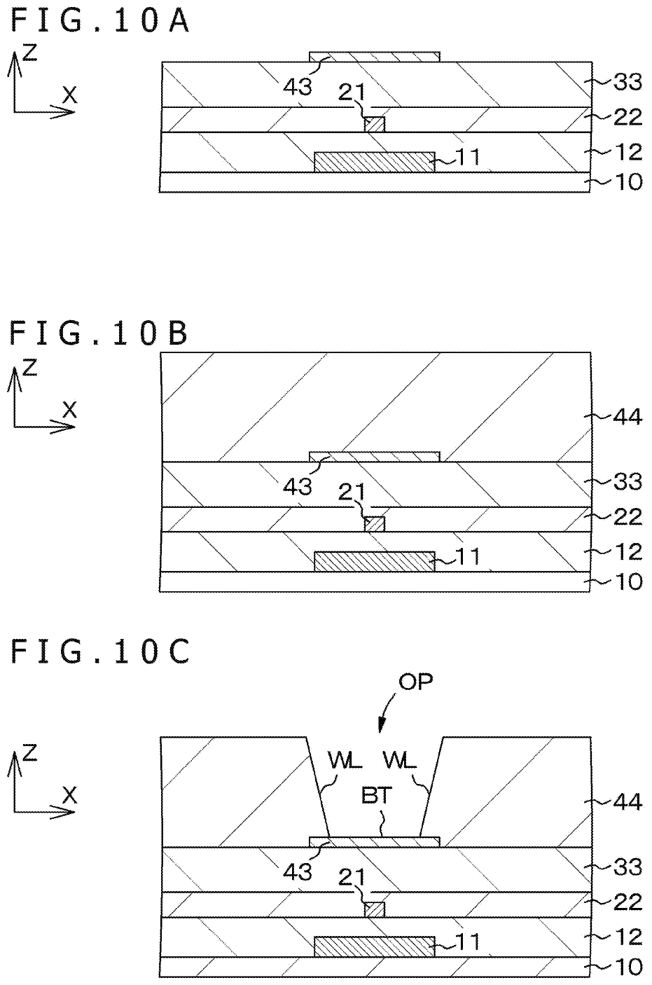

The lower electrode 45, the dielectric film 46, and the upper electrode 47 are formed in an opening portion that is disposed in the interlayer insulating film 44, and the upper surface of the capacitor structure CS is flattened in accordance with the upper surface of the interlayer insulating film 44, which will be explained later in detail with reference to FIGS. 10 to 13. Further, respective end surfaces, on the upper surface of the capacitor structure CS of the lower electrode 45, the dielectric film 46, and the upper electrode 47, are flattened in accordance with the upper surface of the interlayer insulating film 44.

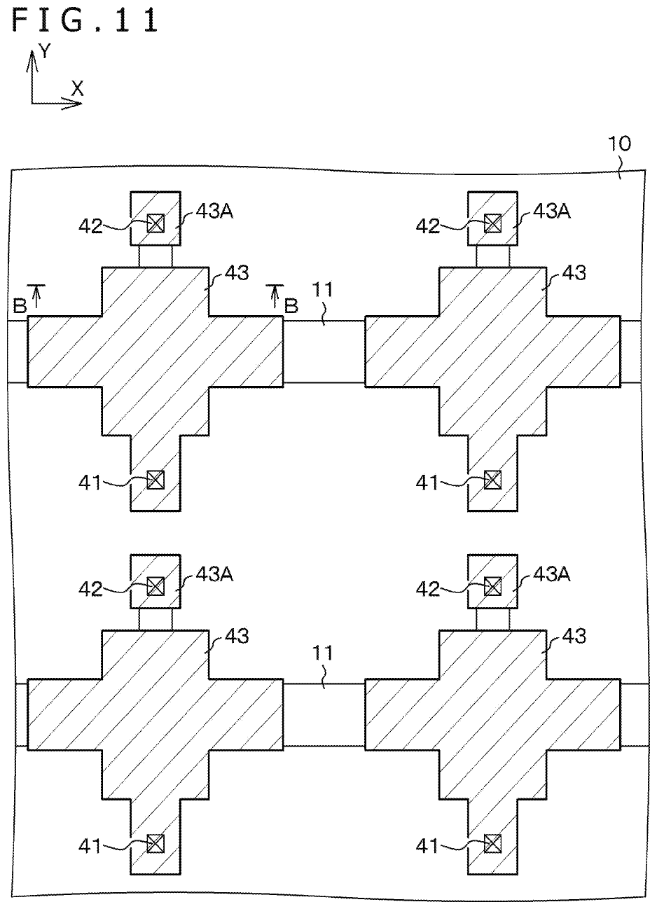

As illustrated in FIG. 6B, the relay electrode 43 and one source/drain region of the transistor TR are connected via a contact 41 passing through the insulating layer 33 and the gate insulating film 22. A pixel voltage is applied from the one source/drain region of the transistor TR to the relay electrode 43. It is to be noted that a relay wire 43A in FIG. 6B passes through the insulating layer 33 and the gate insulating film 22 to the other source/drain region of the transistor TR, and is intended to function as a relay wire for a contact 42. The relay wire 43A is formed in the same layer as the relay electrode 43. A hatched part in FIG. 11 indicates a plan shape of the relay electrode 43 and the island-shaped relay wire 43A.

An insulating layer 49 is formed on the interlayer insulating film 44 in which the capacitor structure CS is embedded. Further, various wiring layers are formed above the capacitor structure CS. That is, as illustrated in FIG. 4B, a wiring layer including the signal line 54 and relay wires 54A and 54B, a wiring layer including the common potential line 63 and a relay wire 63A, and a wiring layer including the relay wire 72, are layered on the insulating layer 49. The transistor array substrate 100 includes a plurality of wiring layers in such a manner. Further, the capacitor structure CS is disposed between the transistor TR and the wiring layers.

Further, a contact 52 between the upper electrode 47 of the capacitor structure CS and the wiring layer including the signal line 54 and the relay wires 54A and 54B is formed so as to be in contact with the conductive material 48 embedded in the recess portion in the upper electrode 47 of the capacitor structure CS by passing through the insulating layer 49 (see FIG. 4B). In addition, a contact 51 (see FIG. 4B) that is extended to the relay electrode 43 or a contact 53 (see FIG. 6B) that is extended to the relay wire 43A is formed on the insulating layer 49 and the interlayer insulating film 44.

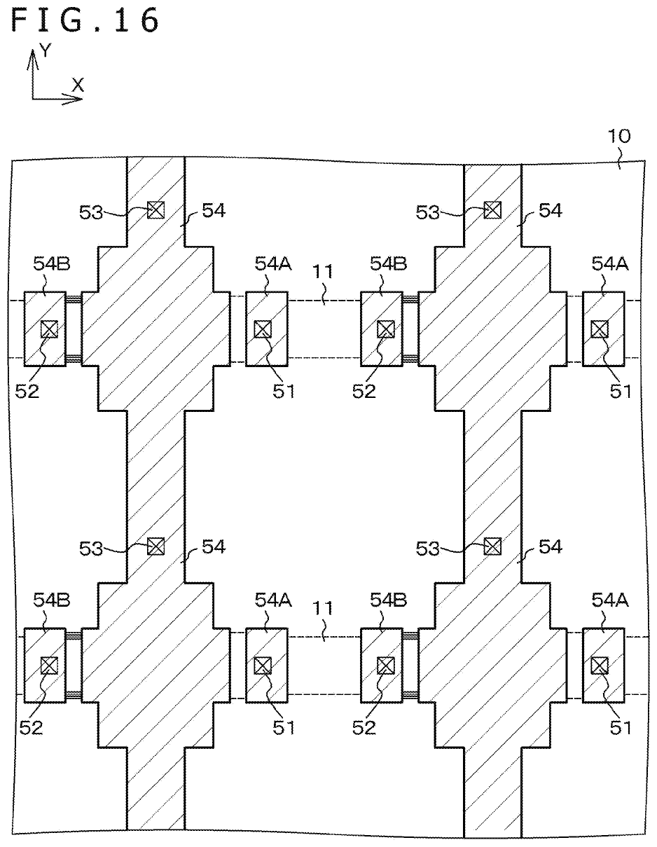

The aforementioned wiring layers will be explained. A signal line 54 extending in a Y direction in the drawings and island-shaped relay wires 54A and 54B are formed on the insulating layer 49. The relay wires 54A and 54B are formed in the same layer as the signal line 54. The signal line 54 is disposed at a position in contact with the contact 53 (see FIG. 6B). The relay wires 54A and 54B are disposed at positions in contact with the contacts 51 and 52, respectively (see FIG. 4B). A hatched part in FIG. 16 indicates a plan shape of the signal line 54 and the island-shaped relay wires 54A and 54B.

As illustrated in FIG. 6B, the signal line 54 is connected to the other source/drain region of the transistor TR via the contact 53, the relay wire 43A, and the contact 42. A pixel voltage supplied from the signal line 54 is applied to the lower electrode 45 of the capacitor structure CS via the transistor TR that is in a conductive state, the contact 41, and the relay electrode 43. The common potential V_{com} is applied to the upper electrode 47 of the capacitor structure CS, which will be explained later. Consequently, after the transistor TR enters a non-conductive state, the pixel voltage is still held by the capacitor structure CS.

An insulating film 55 is formed over the entire surface including an area above the signal line 54 and the relay wires 54A and 54B. A contact 61 that is extended to the relay wire 54A and a contact 62 that is extended to the relay wire 54B are formed on the insulating film 55.

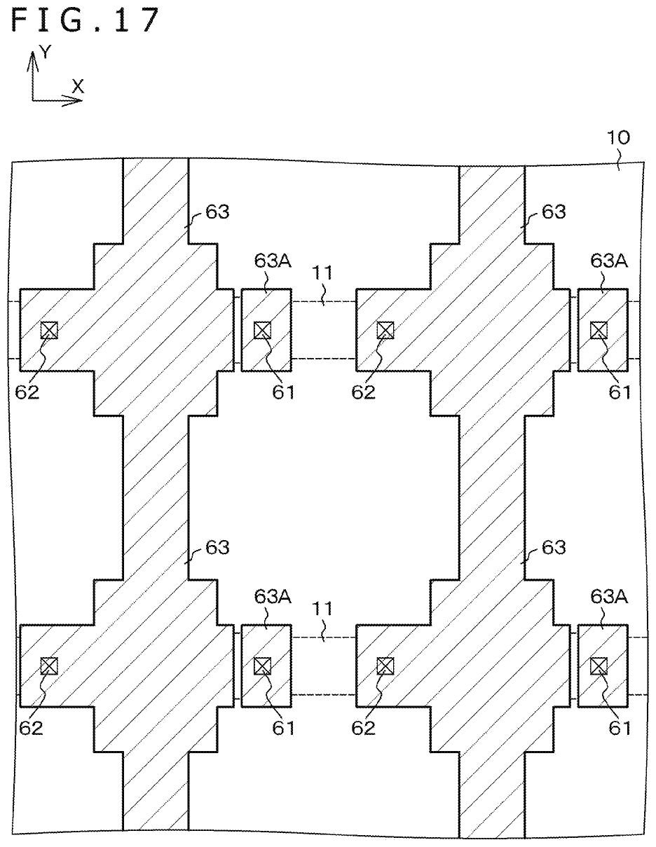

Further, a common potential line 63 extending in a Y direction in the drawings and the island-shaped relay wire 63A are formed on the insulating film 55. The relay wire 63A is formed in the same layer as the common potential line 63. The common potential line 63 is disposed at a position in contact with the contact 62. The relay wire 63A is disposed at a position in contact with the contact 61. A hatched part in FIG. 17 indicates a plan shape of the common potential line 63 and the island-shaped relay wire 63A.

As illustrated in FIG. 4B, the common potential line 63 is connected to the upper electrode 47 of the capacitor structure CS via the contact 62, the relay wire 54B, the contact 52, and the conductive material 48 that is embedded in the recess portion in the upper electrode 47. Consequently, the common potential V_{com} is applied to the upper electrode 47.

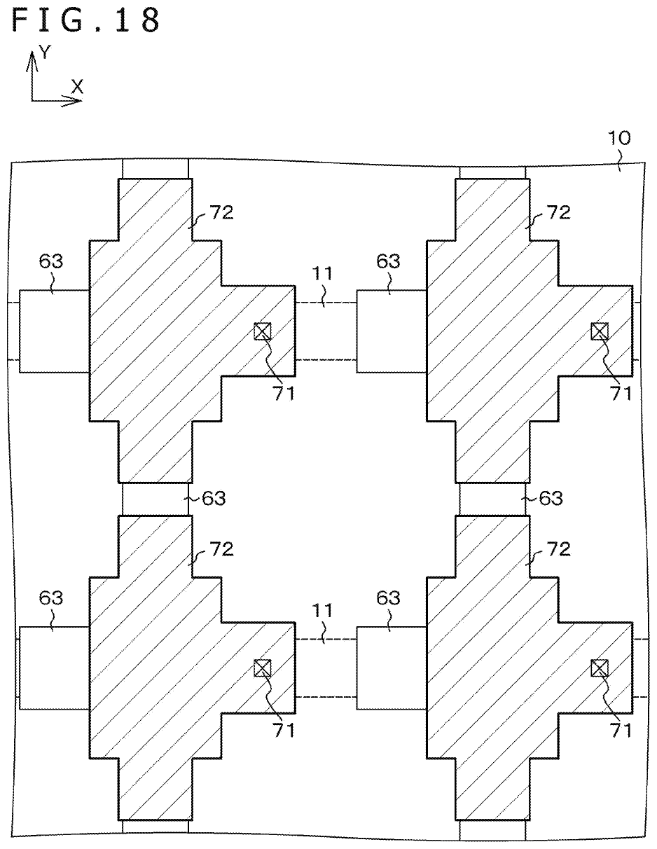

An insulating film 64 is formed over the entire surface including an area above the common potential line 63 and the relay wire 63A. A contact 71 extended to the relay wire 63A is formed on the insulating film 64. Further, the relay wire 72 that is in contact with the contact 71 is formed on the insulating film 64. A hatched part in FIG. 18 indicates a plan shape of the relay wire 72.

As illustrated in FIG. 4B, the relay wire 72 is connected to the relay electrode 43 via the contact 71, the relay wire 63A, the contact 61, the relay wire 54A, and the contact 51. Since the relay electrode 43 is connected to the capacitor structure CS, a pixel voltage held by the capacitor structure CS is supplied to the relay wire 72.

A flattened film 73 is formed over the entire surface including an area above the relay wire 72. Further, the transistor array substrate 100 includes the pixel electrode 81 to which a pixel voltage held by the capacitor structure CS is applied.

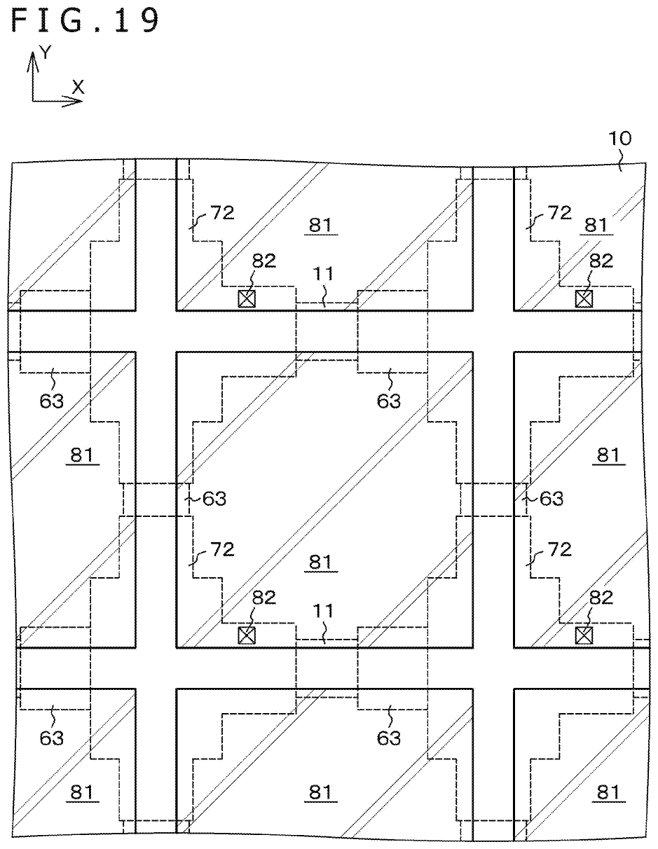

That is, the pixel electrodes 81, which is formed by dividing a transparent conductive material layer into two-dimensional matrixes at a prescribed pitch, is formed on the flattened film 73. Reference sign 82 denotes a contact between the pixel electrode 81 and the relay wire 72. A pixel voltage held by the capacitor structure CS is supplied to the pixel electrode 81. A hatched part in FIG. 19 indicates a plan shape of the pixel electrode 81. It is to be noted that, for example, an orientation film may be formed over the entire surface including an area above the pixel electrode 81.

Next, a transistor array substrate production method will be explained.

As previously explained, the transistor array substrate 100 of the liquid crystal display device 1 includes

the capacitor structure CS and the transistor TR formed on the support substrate 10,

the capacitor structure CS includes
the relay electrode 43,
the lower electrode 45 that has the bottom surface disposed on the relay electrode 43 and has a wall surface extending obliquely with respect to the bottom surface,
the dielectric film 46 that is formed on the lower electrode 45, and
the upper electrode 47 that is formed on the dielectric film 46,

the dielectric film 46 and the upper electrode 47 are formed in accordance with the lower electrode 45, and

the conductive material is embedded in the recess portion in the upper electrode 47.

Further, a production method for the transistor array substrate 100 includes

a step of disposing the relay electrode 43 on the insulating layer 33, forming the interlayer insulating film 44 over the entire surface, and then, forming an opening portion in the interlayer insulating film 44 in such a way that the opening portion has a bottom portion from which the relay electrode 43 is exposed, and has a wall surface obliquely extending with respect to the bottom portion,

a step of subsequently forming a first conductive material layer to form the lower electrode 45, an insulating material layer to form the dielectric film 46, and a second conductive material layer to form the upper electrode 47 sequentially over the entire surface including an inner side of the opening portion,

a step of subsequently forming a third conductive material layer over the entire surface including an area above the upper electrode 47, and

a step of performing, on the entire surface, a flattening process so as to expose the interlayer insulating film 44.

Each of FIGS. 7 to 19 is a schematic partial plan view or a partial cross sectional view for explaining the transistor array substrate production method. It is to be noted that, in principle, illustration of the insulating layers and insulating films is omitted in each plan view, from the point of view of readability. Hereinafter, the production method for the transistor array substrate 100 will be explained in detail with reference to FIGS. 7 to 19.

[Step-100] (see FIG. 7)

First, the scan line 11 is formed on the support substrate 10. Specifically, the support substrate 10 is prepared, and the scan line 11 is formed on the support substrate 10 by a well-known film forming method or a well-known patterning method.

[Step-110] (see FIGS. 8 and 9)

Next, the transistor TR is formed. The insulating film 12 made from silicon oxide, for example, is formed over the entire surface including an area above the scan line 11. Thereafter, the semiconductor material layer 21 constituting the transistor TR is formed on the insulating film 12 by a well-known film forming method or a well-known patterning method (see FIG. 8).

Next, the gate insulating film 22 is formed over the entire surface including an area above the semiconductor material layer 21. Thereafter, an opening is provided in a portion of the gate insulating film 22 corresponding to the contact 31. Subsequently, the gate electrode 32 is formed by a well-known film forming method or a well-known patterning method (see FIG. 9). Accordingly, the transistor TR is formed. Then, the insulating layer 33 is formed over the entire surface including an area above the gate electrode 32.

[Step-120] (see FIGS. 10, 11, 12, 13, 14, and 15)

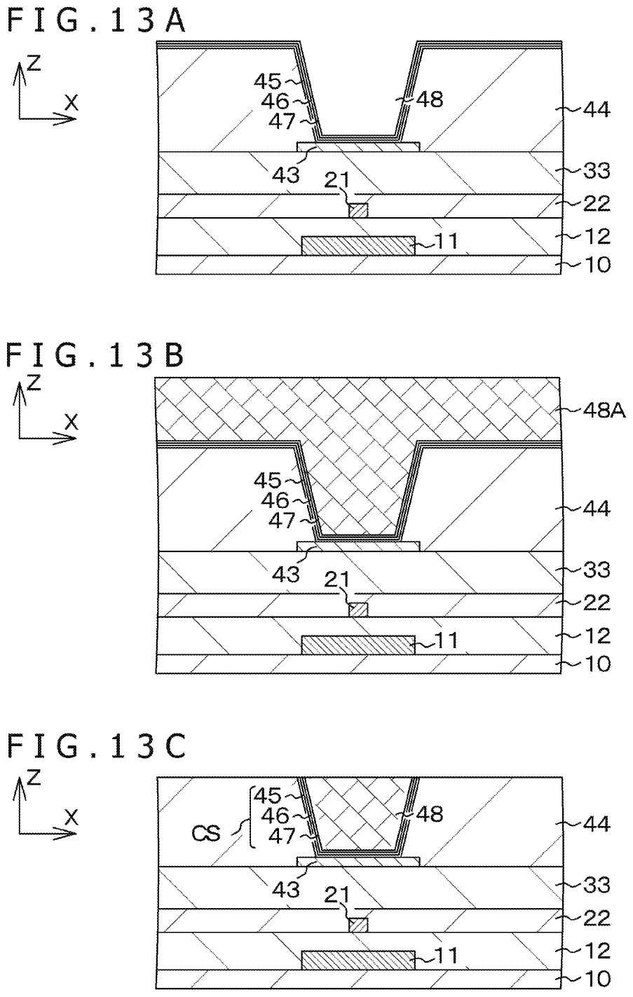

Thereafter, the capacitor structure CS is formed above the insulating layer 33. It is to be noted that FIGS. 10A, 10B, 10C, 13A, 13B, and 13C each schematically illustrate a cross-sectional structure corresponding to a part taken along B-B in FIG. 5A.

First, the relay electrode 43 is provided on the insulating layer 33. More specifically, the contacts 41 and 42 illustrated in FIG. 6B are formed on the insulating layer 33 and the gate insulating film 22, and then, the relay electrode 43 is provided on the insulating layer 33 by a well-known film forming method or a well-known patterning method (see FIG. 10A). In addition, the relay wire 43A is also formed (see FIG. 11).

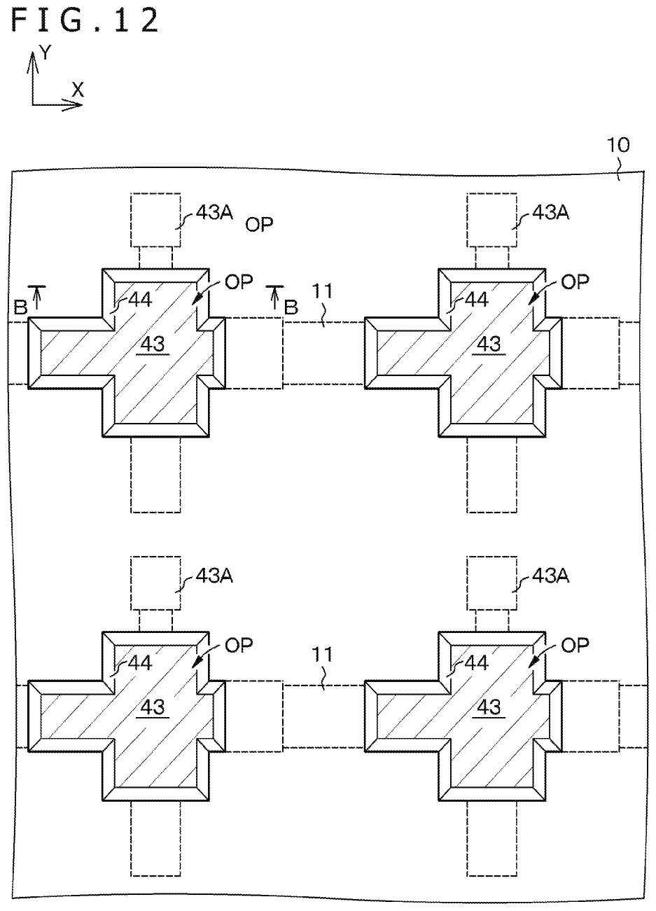

Thereafter, the interlayer insulating film 44 is formed over the entire surface (see 10B). Next, an opening portion OP that has a bottom portion BT from which the relay electrode 43 is exposed, and has a wall surface WL extending obliquely with respect to the bottom portion BT is formed in the interlayer insulating film 44 (see FIG. 10C). FIG. 12 illustrates a plan shape of the opening portion OP in the interlayer insulating film 44. It is to be noted that a hatched part in FIG. 12 indicates a part of the relay electrode 43 exposed from the bottom portion BT of the opening portion OP.

Thereafter, a first conductive material layer to form the lower electrode 45, an insulating material layer to form the dielectric film 46, and a second conductive material layer to form the upper electrode 47 are sequentially formed over the entire surface including the inner side of the opening portion OP (see FIG. 13A). Next, a third conductive material layer 48A is formed over the entire surface including an area above the upper electrode 47.

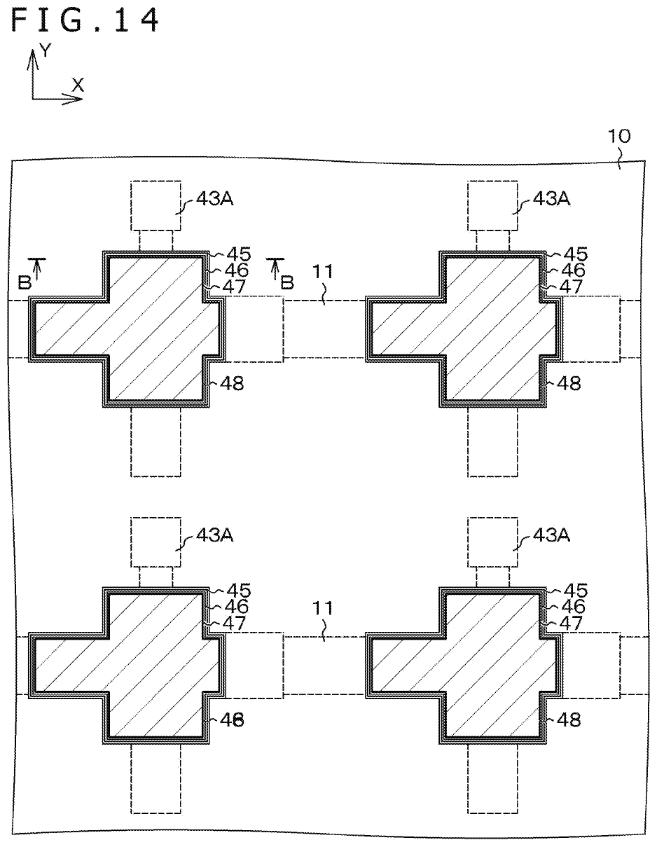

Thereafter, a flattening process to expose the interlayer insulating film 44 is performed (see FIG. 13C). Accordingly, the capacitor structure CS that is embedded in the interlayer insulating film 44 can be formed. In addition, respective end surfaces, on the upper surface of the capacitor structure CS of the lower electrode 45, the dielectric film 46, and the upper electrode 47, are flattened in accordance with the upper surface of the interlayer insulating film 44. FIG. 14 illustrates a plan shape of the capacitor structure CS that is embedded in the interlayer insulating film 44. A hatched part in FIG. 14 indicates the conductive material 48 that is embedded in a recess portion in the upper electrode 47.

It is to be noted that the end surface, on the upper surface of the capacitor structure CS of the dielectric film 46, can be inwardly recessed from respective end surfaces of the lower electrode 45 and the upper electrode 47. Specifically, a step of further etching an end of the dielectric film 46 is only required to be performed after the aforementioned flattening process is performed. Accordingly, leakage in the end surfaces can be reduced.

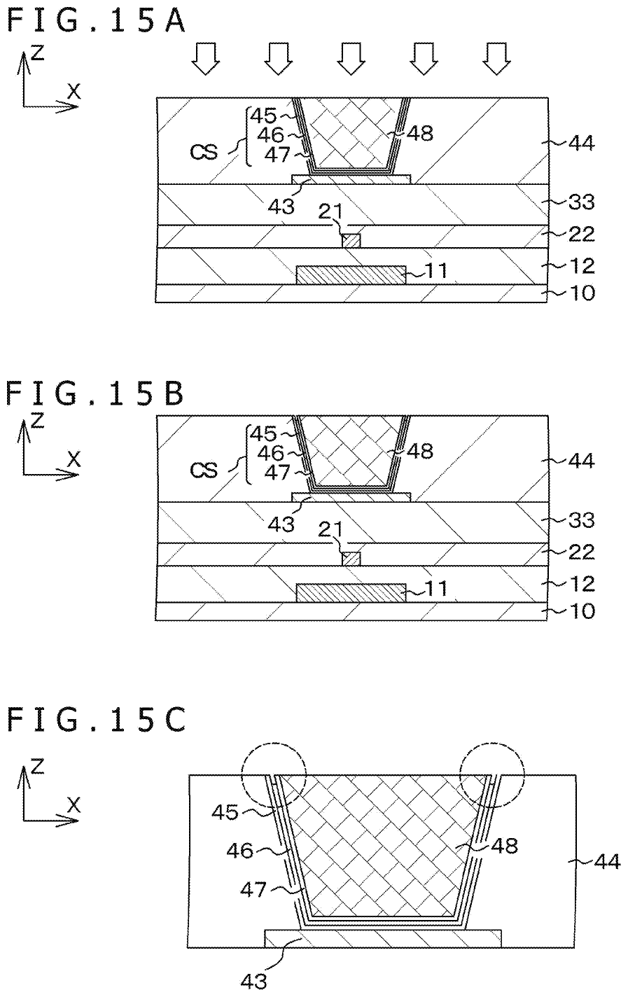

FIG. 15 is a partial cross-sectional view for explaining the step of etching an end of the dielectric film.

For example, etching is performed with a chemical liquid that can ensure the etching selectivity of the dielectric film 46 with respect to the lower electrode 45 and the upper electrode 47 (see FIG. 15A). Accordingly, the end surface, on the upper surface of the capacitor structure CS of the dielectric film 46, is recessed (see FIG. 15B). FIG. 15C is a schematic enlarged view of the recessed portion of the dielectric film 46.

The recessed portion in the dielectric film 46 is coated with the insulating layer 49, which will be explained later. In a case where the insulating layer 49 has a recess, the insulating layer 49 may be flattened, as appropriate. The step of etching the end of the dielectric film 46 has been explained so far.

[Step-130] (see FIG. 16) The insulating layer 49 is formed over the entire surface including an area above the interlayer insulating film 44 and the embedded capacitor structure CS. Next, the contact 52 in contact with the conductive material 48 of the capacitor structure CS is formed on the insulating layer 49, and the contacts 51 and 53 are simultaneously formed on the insulating layer 49 and the interlayer insulating film 44. Thereafter, the signal line 54 is formed by a well-known film forming method or a well-known patterning method, and further, the relay wires 54A and 54B are formed. Next, the insulating film 55 is formed over the entire surface.

[Step-140] (see FIG. 17)

Next, the common potential line 63 is formed on the insulating film 55. First, after the contacts 61 and 62 are formed on the insulating film 55, the common potential line 63 is formed by a well-known film forming method or a well-known patterning method, and the relay wire 63A is simultaneously formed (see FIG. 17). Thereafter, the insulating film 64 is formed over the entire surface.

[Step-150] (see FIG. 18)

Next, the relay wire 72 is formed on the insulating film 64. First, the contact 71 is formed on the insulating film 64, and then, the relay wire 72 is formed by a well-known film forming method or a well-known patterning method (see FIG. 18). Thereafter, the flattened film 73 is formed over the entire surface.

[Step-160] (see FIG. 19)

Next, the pixel electrodes 81 are formed on the flattened film 73. First, an opening is formed in a portion of the flattened film 73 corresponding to the contact 82, and then, a transparent conductive material layer is formed over the entire surface. Then, the transparent conductive material layer is divided by a well-known patterning method. Accordingly, the pixel electrodes 81 can be obtained.

The production method for the transistor array substrate 100 has been explained so far. It is to be noted that, in a case of producing the liquid crystal display device 1, a step of forming an orientation film or the like on the transistor array substrate 100, placing the resultant substrate to be opposed to a counter substrate with a liquid crystal material layer disposed between the substrates, and sealing the periphery thereof, may be performed.

In the capacitor structure CS of the transistor array substrate 100, a side wall portion thereof also functions as a capacitance so that a capacitance per unit area can be increased. In addition, when the recessed portion in the upper electrode 47 is filled with the conductive material, a contact can be disposed directly on the capacitor structure CS. As a result, connection to the contact can be established without involving deterioration of the efficiency of a plan layout.

In addition, since the recessed portion in the upper electrode 47 is filled with the conductive material, generation of a void in an interlayer film formed on the conductive material is suppressed. Accordingly, the flatness and hygroscopicity are improved. Therefore, a step between various structures positioned above the capacitor structure CS is suppressed, and the thickness of the liquid crystal material layer that is held between the counter substrate and the substrate can be made uniform.

Various modifications of the aforementioned transistor array substrate can be made. Hereinafter, the various modifications will be explained.

### First Modification

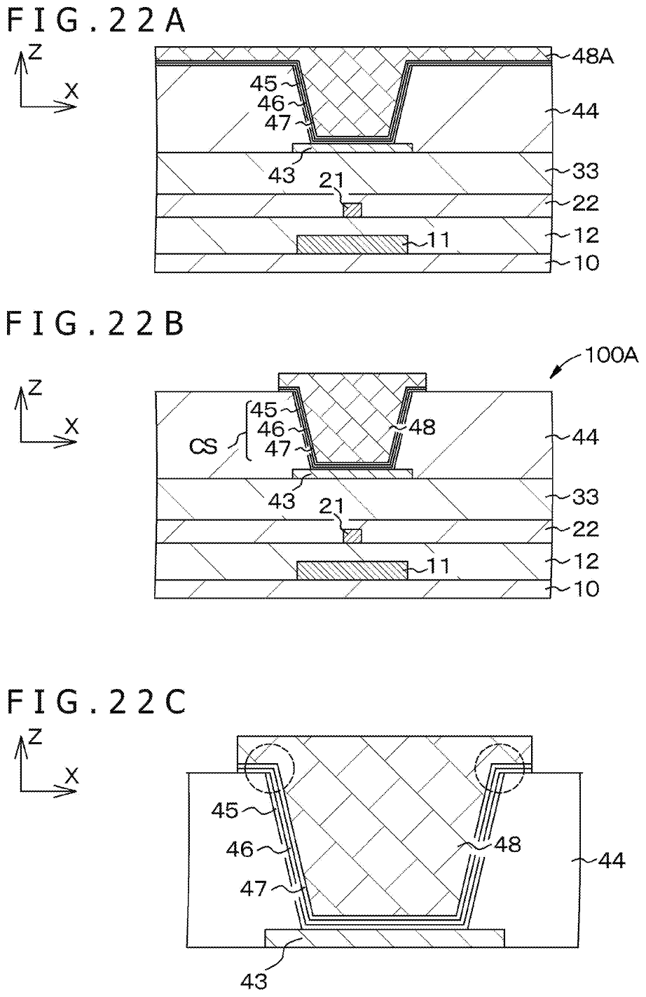

In the capacitor structure CS of a transistor array substrate 100A according to a first modification, the lower electrode 45 is formed in an opening portion that is disposed in the interlayer insulating film 44, and an end surface of the lower electrode 45 is flattened in accordance with the upper surface of the interlayer insulating film 44, as illustrated in FIG. 22C, which will be explained later. Then, the dielectric film 46 is formed so as to coat the end surface of the lower electrode 45 and the interlayer insulating film 44 region around the end surface of the lower electrode 45. The upper electrode 47 and the conductive material 48 are formed in the similar manner. As a result, the end surface of the lower electrode 45 is separated from the end surface of the upper electrode 47 so that leakage in the end surfaces can be reduced.

Aside from the difference in the capacitor structure CS, the transistor array substrate 100A according to the first modification has a structure identical to that of the transistor array substrate 100 having been explained in the first embodiment. Hereinafter, a production method for the transistor array substrate 100A according to the first modification will be explained.

The production method for the transistor array substrate 100A includes

a step of providing the relay electrode 43 on the insulating layer 33, forming the interlayer insulating film 44 over the entire surface, and then, forming an opening portion OP in the interlayer insulating film 44 in such a way that the opening portion has a bottom portion from which the relay electrode 43 is exposed, and has a wall surface extending obliquely with respect to the bottom portion,

a step of subsequently forming a first conductive material layer to form the lower electrode 45 over the entire surface including the inner side of the opening portion OP,

a step of performing, on the entire surface, a flattening process so as to expose the interlayer insulating film 44, and

a step of subsequently forming the dielectric film 46 that coats the end surface of the lower electrode 45 and the interlayer insulating film 44 region around the dielectric film 46, the upper electrode 47 that is disposed on the dielectric film 46, and the conductive material 48 that is embedded in a recess portion in the upper electrode 47.

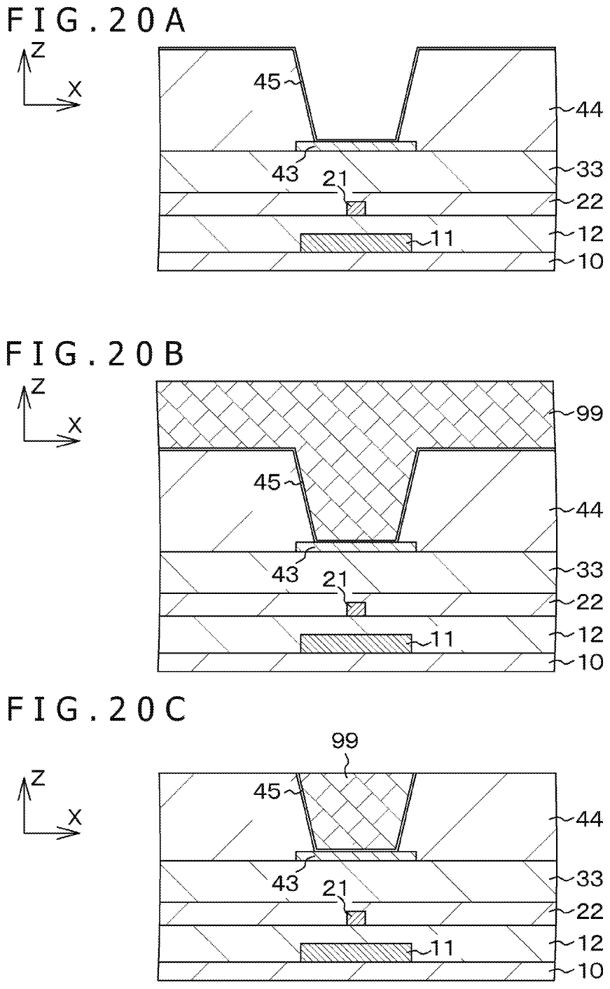

FIGS. 20, 21, and 22 are schematic partial cross-sectional views for explaining the production method for the transistor array substrate according to the first modification. It is to be noted that FIGS. 20 to 22 each schematically illustrate a cross-sectional structure corresponding to a part taken along B-B in FIG. 5A.

[Step-100A]

First, steps identical to the aforementioned [Step-100] and [Step-110] are performed, and then, the aforementioned [Step-120] of forming the opening portion OP in the interlayer insulating film 44 is performed (see FIG. 10C).

[Step-110A]

Next, the lower electrode 45 is formed in the opening portion OP that is disposed in the interlayer insulating film 44.

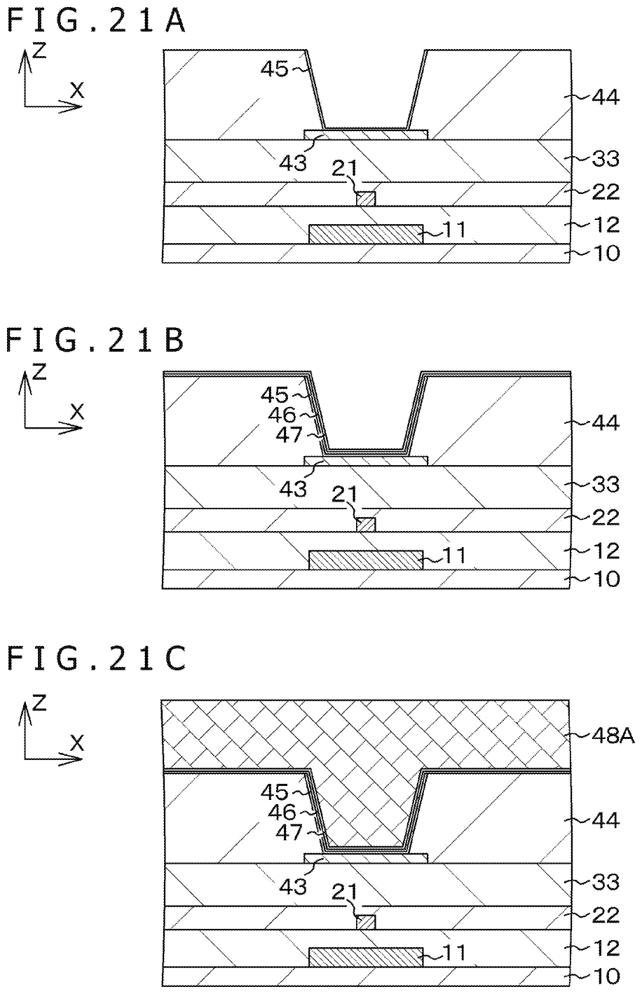

First, a first conductive material layer to form the lower electrode 45 is formed over the entire surface including the inner side of the opening portion OP (see FIG. 20A). Thereafter, a flattening process is performed on the entire surface in such a way that the interlayer insulating film 44 is exposed. Pre-processing of forming a sacrificial layer 99 that is made from tungsten, for example, over the entire surface is performed (see FIG. 20B). Further, the flattening process is performed to expose the interlayer insulating film 44 (see FIG. 20C). Next, the sacrificial layer 99 that remains in the recess portion is removed (see FIG. 21A). Consequently, the lower electrode 45 is formed in the opening portion OP.

[Step-110A]

Thereafter, the dielectric film 46 that coats the end surface of the lower electrode 45 and the interlayer insulating film 44 region around the end surface of the lower electrode 45, the upper electrode 47 that is disposed on the dielectric film 46, and the conductive material 48 that is embedded in a recess portion in the upper electrode 47 are formed.

An insulating material layer to form the dielectric film 46, and a second conductive material layer to form the upper electrode 47 are sequentially formed over the entire surface (see FIG. 21B). Next, the third conductive material layer 48A is formed over the entire surface including an area above the upper electrode 47.

Thereafter, a flattening process is performed in such a way that the third conductive material layer 48A remains on the interlayer insulating film 44 (see FIG. 22A). Next, the dielectric film 46, the upper electrode 47, and the conductive material 48 are patterned by a well-known method to coat the end surface of the lower electrode 45 and the interlayer insulating film 44 region around the end surface of the lower electrode 45 (FIG. 22B). Accordingly, the capacitor structure CS according to the first modification can be obtained.

[Step-120A]

Thereafter, steps identical to the aforementioned [Step-130] to [Step-160] are performed. As a result, the transistor array substrate 100A can be obtained.

FIG. 22C is an enlarged schematic diagram of a part of the lower electrode 45 coated with the dielectric film 46. Compared with the structure of the first embodiment, the end surface of the lower electrode 45 is further separated from the end surface of the upper electrode 47. Accordingly, leakage in the end surfaces can be further reduced.

### Second Modification

In the above embodiment, the lower electrode has one bottom surface. In a case where the width of the relay electrode is wide, the lower electrode can have a plurality of bottom surfaces. Thus, the area of the wall surface is increased, and the efficiency of a plan layout is improved. Moreover, the conductive material can be easily embedded.

Aside from the difference in the structure of the capacitor structure CS, the structure of a transistor array substrate 100B according to a second modification is identical to that of the transistor array substrate 100 having been explained in the first embodiment. Hereinafter, a production method for the transistor array substrate 100B according to the second modification will be explained.

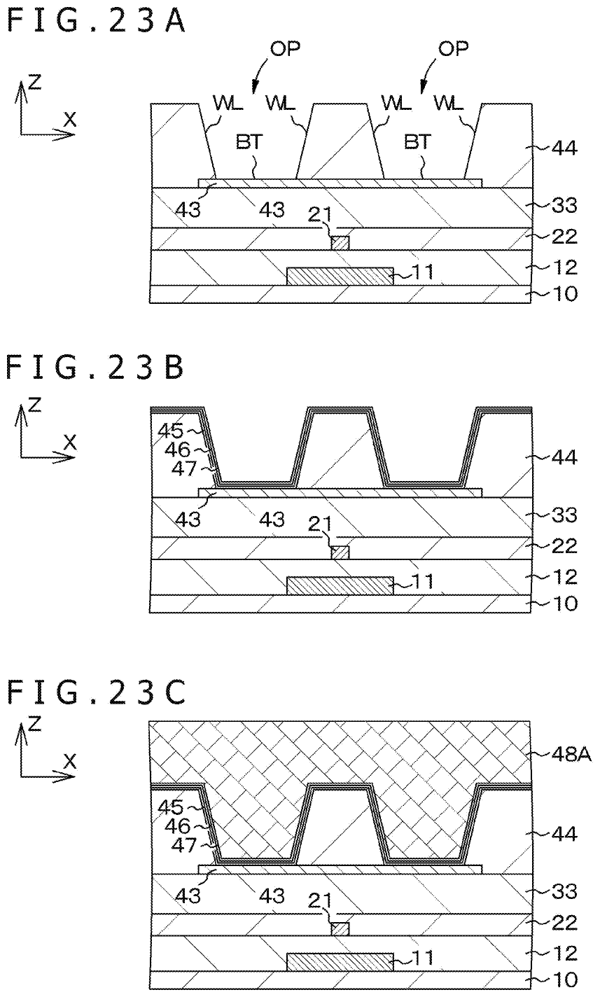

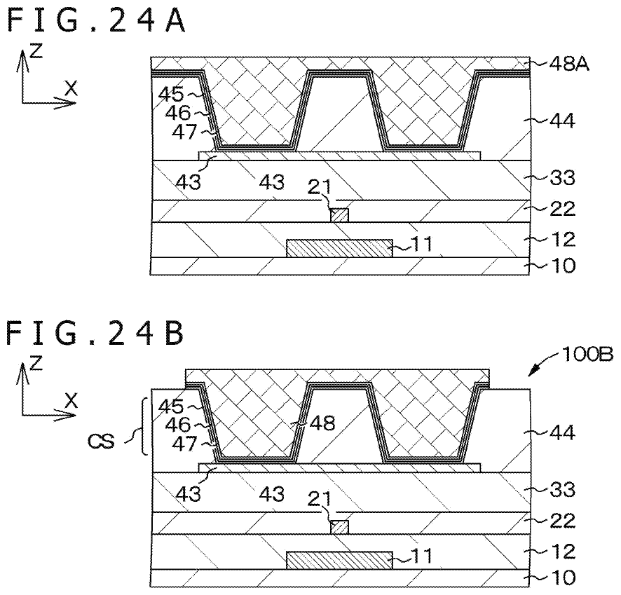

FIGS. 23 and 24 are schematic partial cross-sectional views for explaining the transistor array substrate production method according to the second modification. FIGS. 23 and 24 each schematically illustrate a cross-sectional structure corresponding to a part taken along B-B in FIG. 5A.

[Step-100B]

First, steps identical to the aforementioned [Step-100] and [Step-110] are performed, and then, a step of the aforementioned [Step-120] of forming the opening portion OP in the interlayer insulating film 44 is performed. However, a plurality of the opening portions OP is formed in such a way that a plurality of bottom portions from which the relay electrode 43 is exposed is provided (see FIG. 23A). Two opening portions OP are provided in FIGS. 23 and 24, but this is just an example.

[Step-110B]

Thereafter, a first conductive material layer to form the lower electrode 45, an insulating material layer to form the dielectric film 46, and a second conductive material layer to form the upper electrode 47 are sequentially formed over the entire surface including the inner side of each of the opening portions OP (see FIG. 23B). Next, the third conductive material layer 48A is formed over the entire surface including an area above the upper electrode 47 (see FIG. 23C).

Thereafter, a flattening process is performed in such a way that the third conductive material layer 48A remains on the interlayer insulating film 44 (see FIG. 24A). Next, the lower electrode 45, the dielectric film 46, the upper electrode 47, and the conductive material 48 are patterned by a well-known method to coat the interlayer insulating film 44 region around the opening portions OP (FIG. 24B). Accordingly, the capacitor structure CS according to the third modification can be obtained.

[Step-120B]

Next, steps identical to the aforementioned [Step-130] to [Step-160] are performed. Accordingly, the transistor array substrate 100B is obtained.

### Third Modification

The signal line 54, the common potential line 63, and the relay wire 72 in the transistor array substrate 100 are formed by aluminum (Al). The signal line 54 etc., may be formed by copper (Cu) because copper has an excellent allowance value of a resistivity and an excellent allowance value of a current density.

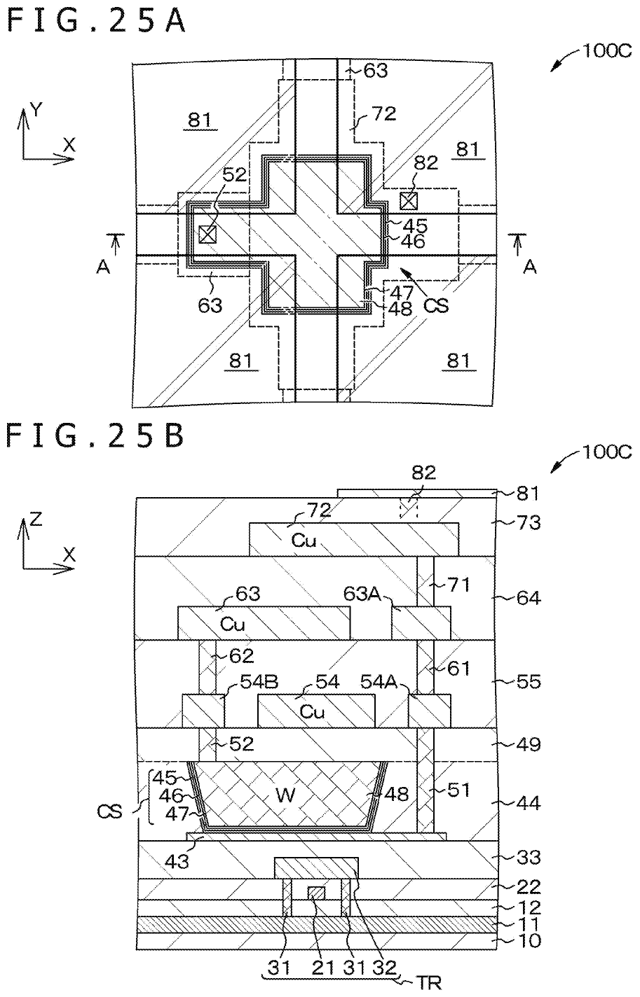

FIGS. 25A and 25B are diagrams for explaining a cross-sectional structure of a transistor array substrate according to a third modification. FIG. 25A is a schematic partial plan view including an area between pixel electrodes in the transistor array substrate. FIG. 25B is a schematic cross-sectional view of a part taken along A-A in FIG. 25A.

In a transistor array substrate 100C, the signal line 54, the common potential line 63, the relay wire 72, and a connection wire formed in the same layer are formed by copper (Cu).

However, a copper wire is inferior in light shielding properties to an aluminum wire. Therefore, in order to reduce leakage in the transistor TR caused by incident external light, it is preferable to use, as the conductive material 48 which is embedded in the capacitor structure CS positioned above the transistor TR, tungsten (W) which has high light shielding properties. It is to be noted that tungsten silicide (WSi) can be alternatively used as the conductive material 48.

### Fourth Modification

In contrast to the third modification, a fourth modification uses, as the conductive material 48 which is embedded in the capacitor structure CS positioned above the transistor TR, aluminum (Al) which has high light reflectivity.

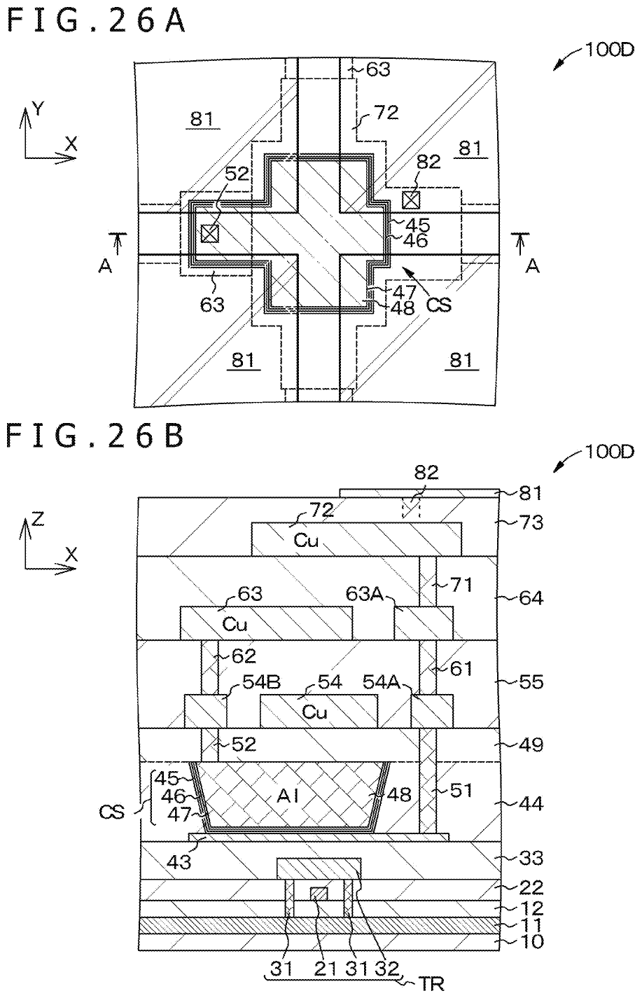

FIGS. 26A and 26B are diagrams for explaining a cross-sectional structure of a transistor array substrate according to the fourth modification. FIG. 26A is a schematic partial plan view including an area between pixel electrodes in the transistor array substrate. FIG. 26B is a schematic partial cross sectional view of a part taken along A-A in FIG. 26A.

Also in a transistor array substrate 100D, the signal line 54, the common potential line 63, the relay wire 72, and a connection wire formed in the same layer are formed by copper (Cu). Further, aluminum (Al) which has high light reflectivity is used as the embedded conductive material 48 in the capacitor structure CS.

### Fifth Modification

A fifth modification differs from the first embodiment in that a wall-like light shielding film with which the transistor TR is enclosed is provided. As a result, leakage in the transistor TR caused by incident external light can be reduced. Aside from the feature of providing the light shielding film, the structure of a transistor array substrate 100E according to the fifth modification is identical to that of the transistor array substrate 100 having been explained in the first embodiment.

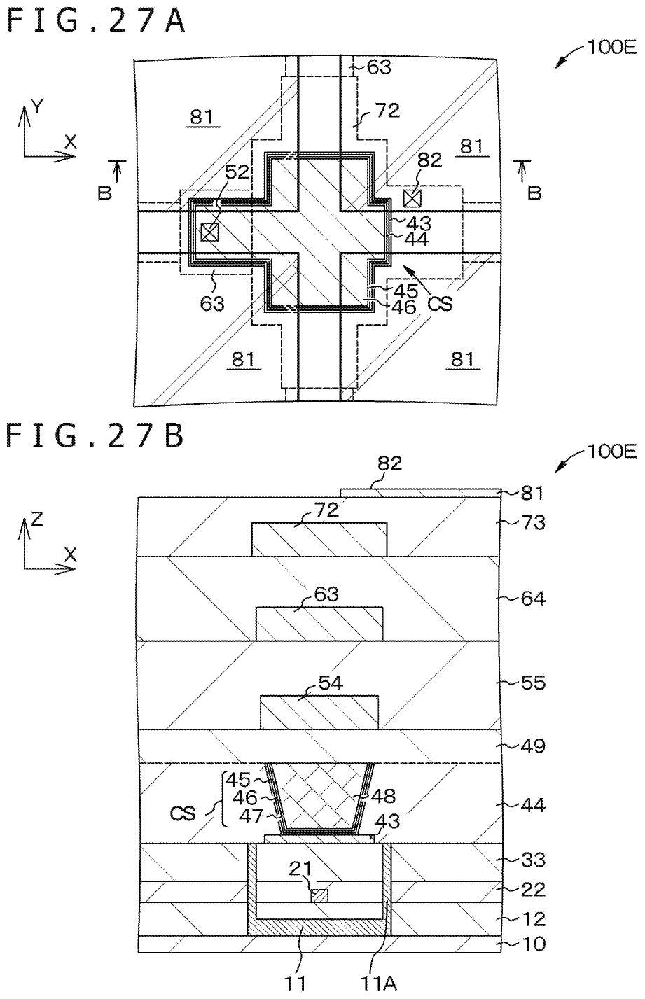

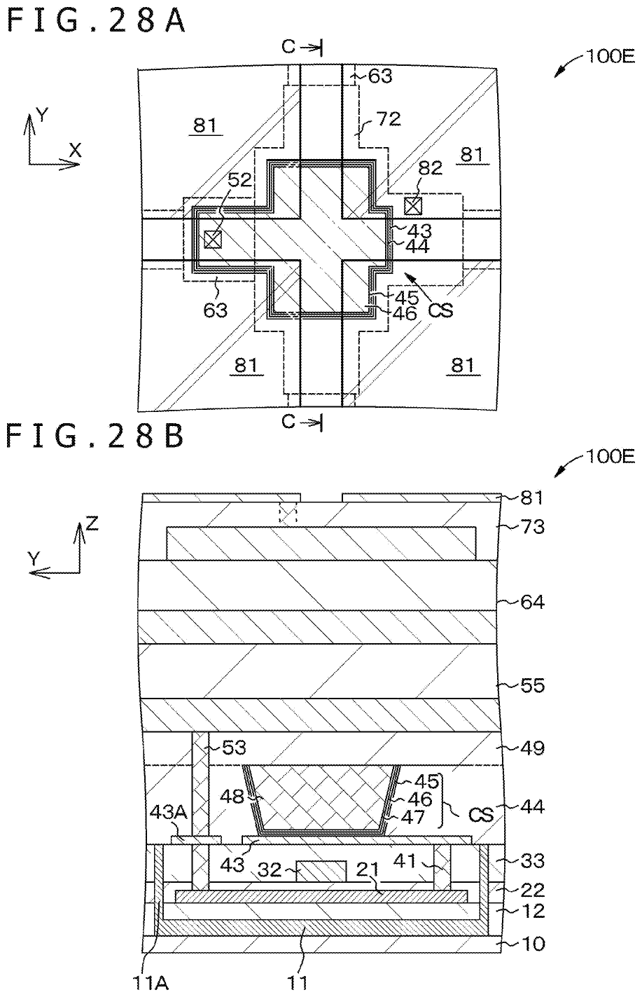

FIGS. 27A and 28A are schematic partial plan views each including an area between pixel electrodes in the transistor array substrate. FIG. 27B is a schematic cross-sectional view of a part taken along B-B in FIG. 27A. FIG. 28B is a schematic cross-sectional view of a part taken along C-C in FIG. 28A.

In the transistor array substrate 100E, the transistor TR is disposed above the scan line 11 that is disposed on the support substrate 10. Further, the periphery of the transistor TR is enclosed with a wall-like lateral light shielding film 11A extending in a direction that is normal to the support substrate (see FIGS. 27B and 28B).

The lateral light shielding film 11A passes through the insulating film 12, the gate insulating film 22, and the insulating layer 33, and is formed along an edge of the scan line 11. An opening along the edge of the scan line 11 is formed in the insulating film 12, the gate insulating film 22, and the insulating layer 33, and then, tungsten (W) or tungsten silicide (WSi), for example, is embedded in the opening. Accordingly, the lateral light shielding film 11A can be formed.

With the transistor array substrate 100E, light entering from a direction of a side surface of the transistor TR is also shielded by the lateral light shielding film 11A. Therefore, leakage in the transistor TR caused by incident external light can be further reduced.

### Sixth Modification

In the transistor array substrate 100 according to the first embodiment, the capacitor structure CS is disposed between the transistor and the wiring layer. In contrast, in a transistor array substrate 100F according to a sixth modification, the capacitor structure CS is disposed between wiring layers.

More specifically, the capacitor structure CS of the sixth modification is disposed between a wiring layer including the common potential line 63 etc., and a wiring layer including the relay wire 72.

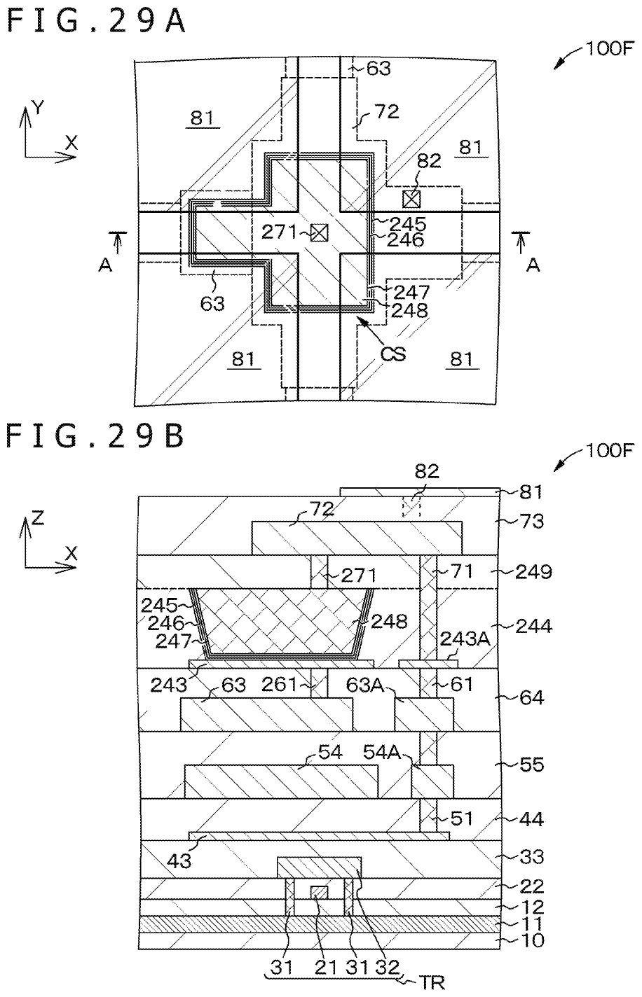

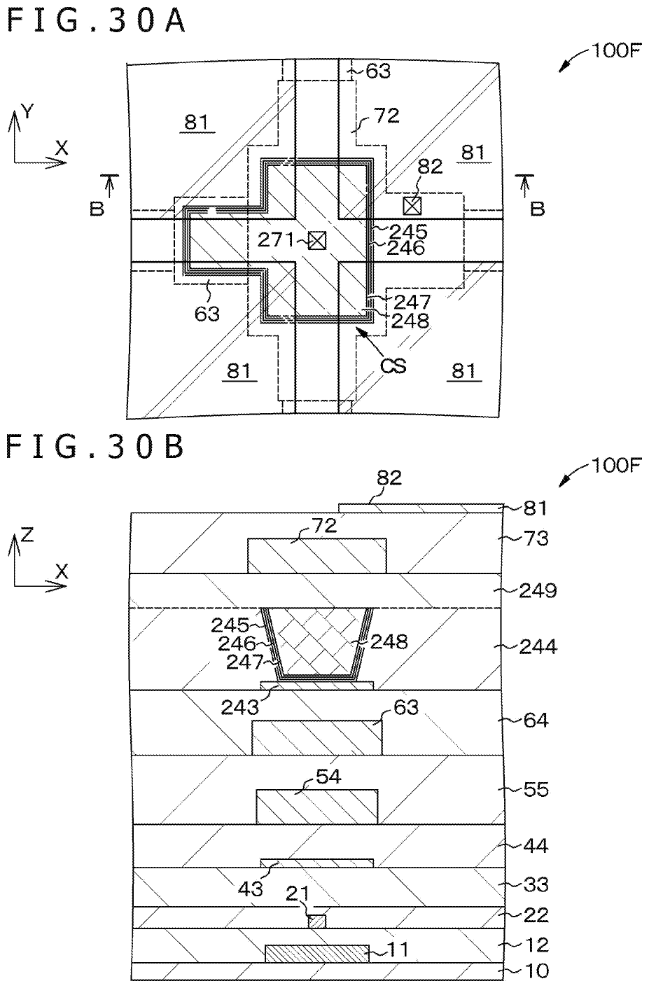

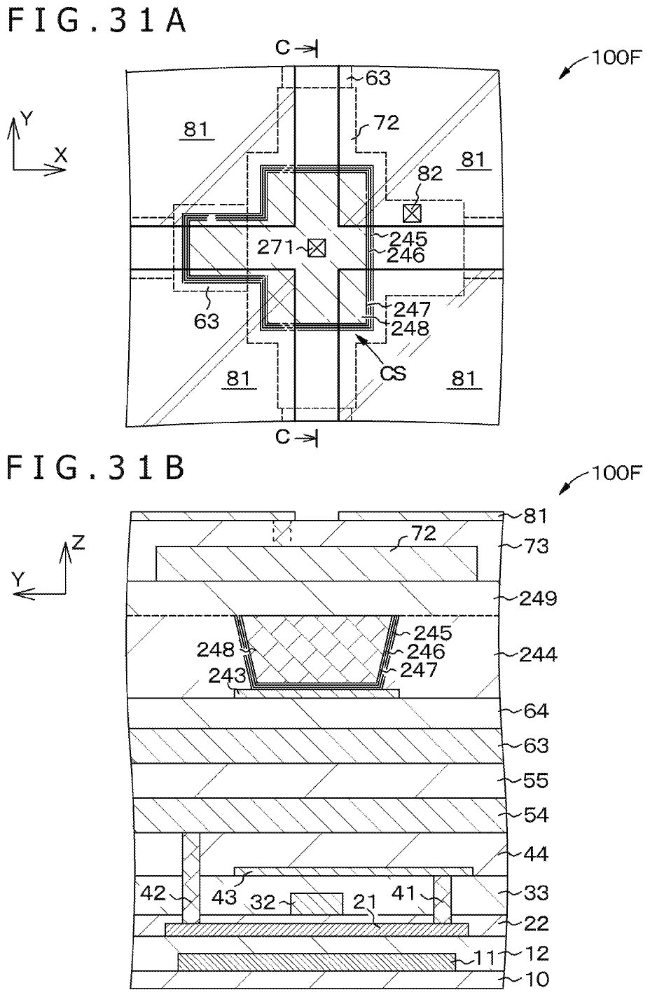

FIGS. 29A, 30A, and 31A are schematic partial plan views each including an area between pixel electrodes in the transistor array substrate. FIG. 29B is a schematic cross-sectional view of a part taken along A-A in FIG. 29A. FIG. 30B is a schematic cross-sectional view of a part taken along B-B in FIG. 30A. FIG. 31B is a schematic cross-sectional view of a part taken along C-C in FIG. 31A.

The insulating film 64 is formed over the entire surface including an area above the common potential line 63 and the relay wire 63A. A relay electrode 243 is formed on the insulating film 64. The common potential line 63 and the relay electrode 243 are connected via a contact 261 illustrated in FIG. 29B. The common potential V_{com} is applied to the relay electrode 243. It is to be noted that a relay wire 243A illustrated in FIG. 29B is disposed so as to be connected to the contact 61, and is formed in the same layer as the relay electrode 243.

The capacitor structure CS is formed so as to be embedded in an interlayer insulating film 244. Reference sign 245 denotes a lower electrode. Reference sign 246 denotes a dielectric film. Reference sign 247 denotes an upper electrode. Reference sign 248 denotes a conductive material that is embedded in a recess portion in the upper electrode. The capacitor structure CS can be formed basically by steps identical to those having been explained in the first embodiment. The common potential V_{com} is applied to the lower electrode 245 via the relay electrode 243.

An insulating layer 249 is formed over the entire surface including an area above the capacitor structure CS. The relay wire 72 is formed on the insulating layer 249. A contact 271 illustrated in FIG. 29B is disposed to connect the relay wire 72 to the upper electrode 247 of the capacitor structure CS, and is formed so as to be in contact with the conductive material 248 that is embedded in a recess portion in the upper electrode 247. In addition, the relay wire 72 is connected to the relay electrode 43 via the contact 71 passing through the insulating layer 249 and the interlayer insulating film 244, and via the relay wire 243A and the contact 61 etc.

As illustrated in FIG. 31B, the signal line 54 is connected to the other source/drain region of the transistor TR via the contact 42. A pixel voltage supplied from the signal line 54 is applied to the transistor TR that is in a conductive state, the contact 41, and the relay electrode 43. As previously explained with reference to FIG. 29B, the relay electrode 43, the relay wire 72, and the upper electrode 247 of the capacitor structure CS are connected. A pixel voltage is applied to the upper electrode 247 of the capacitor structure CS. Consequently, even after the transistor TR enters a non-conductive state, the pixel voltage is still held by the capacitor structure CS.

In this configuration, a shield can be omitted because coupling of the signal line in the first layer and the common potential line in the second layer is suppressed. Moreover, the plan layout of the capacitor structure CS can be increased because contacts from a lower layer are reduced.

### Seventh Modification

In the transistor array substrate 100 according to the first embodiment, the capacitor structure CS is disposed between the transistor and the wiring layer. In contrast, in a transistor array substrate 100G according to a seventh modification, the capacitor structure CS is disposed between wiring layers.

More specifically, the capacitor structure CS of the seventh modification is disposed between a wiring layer including the signal line 54 etc. and a wiring layer including the common potential line 63.

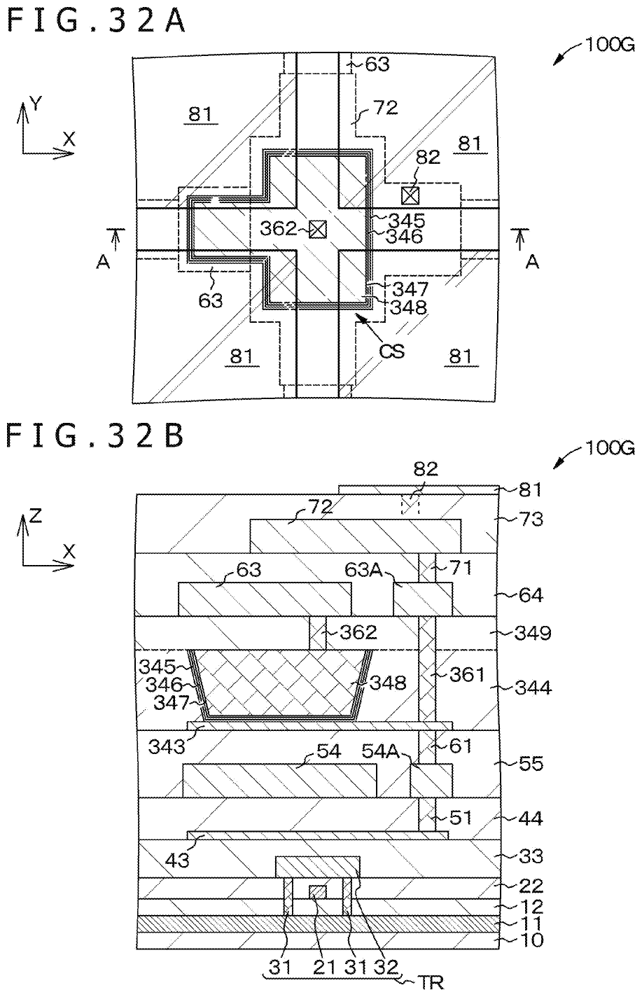

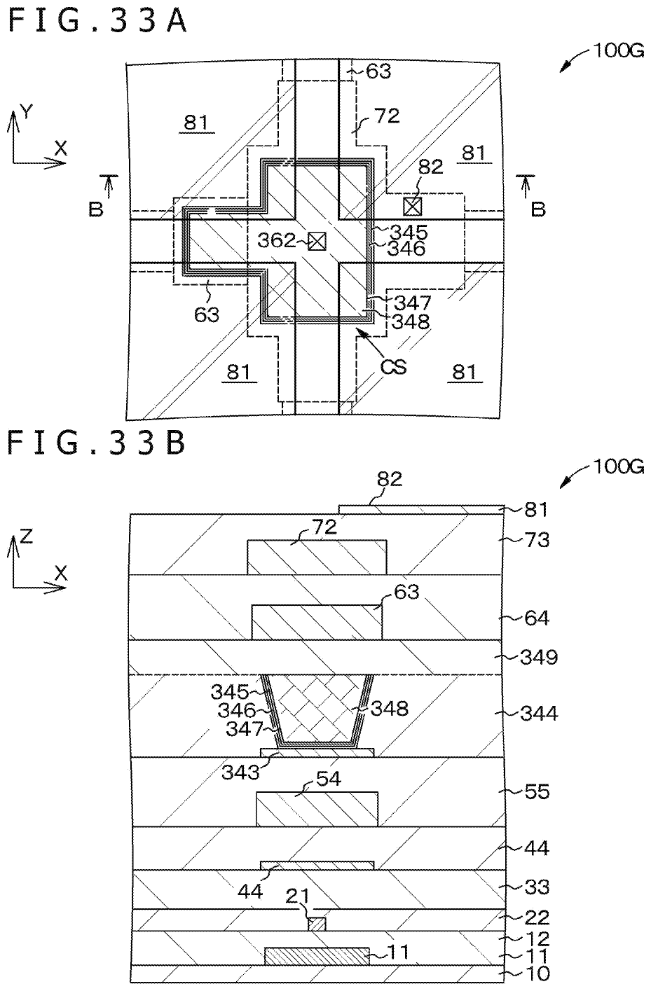

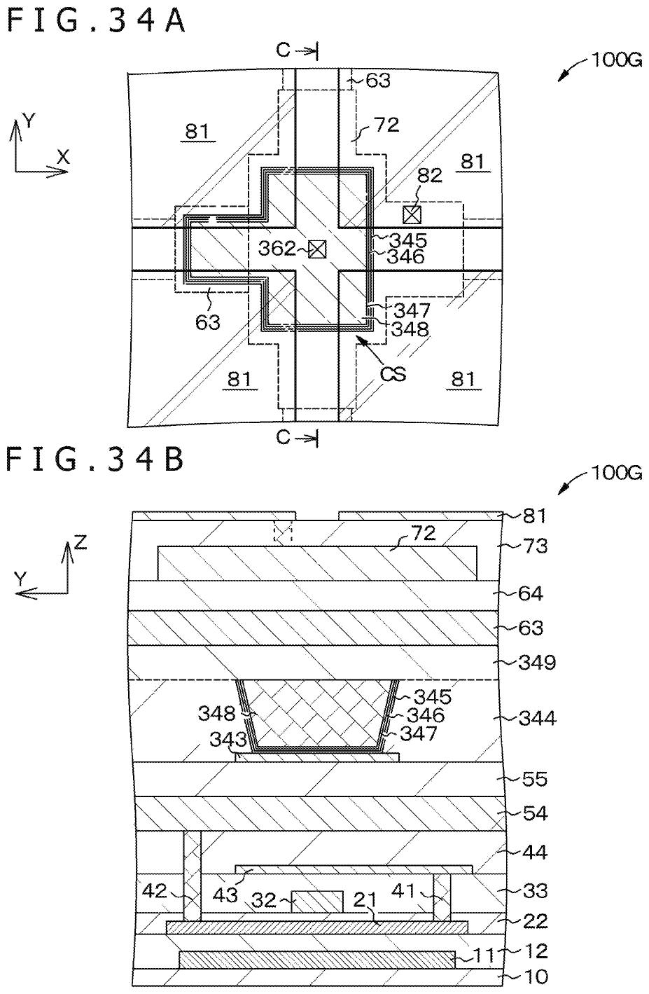

FIGS. 32A, 33A, and 34A are schematic partial plan views each including an area between pixel electrodes in the transistor array substrate. FIG. 32B is a schematic cross-sectional view of a part taken along A-A in FIG. 32A. FIG. 33B is a schematic cross-sectional view of a part taken along B-B in FIG. 33A. FIG. 34B is a schematic cross-sectional view of a part taken along C-C in FIG. 34A.

The insulating film 55 is formed over the entire surface including an area above the signal line 54 and the relay wire 54A. A relay electrode 343 is formed on the insulating film 55. The relay electrode 343 and the relay electrode 43 are connected via the contact 61, the relay wire 54A, and the contact 51 illustrated in FIG. 32B. As previously explained in the [Sixth Modification], a pixel voltage supplied from the signal line 54 is applied to the transistor TR that is in a conductive state, the contact 41, and the relay electrode 43.

The capacitor structure CS is formed so as to be embedded in an interlayer insulating film 344. Reference sign 345 denotes a lower electrode. Reference sign 346 denotes a dielectric film. Reference sign 347 denotes an upper electrode. Reference sign 348 denotes a conductive material that is embedded in a recess portion in the upper electrode 347. The capacitor structure CS can be basically formed by steps identical to the steps that have been explained in the first embodiment. The pixel voltage is applied to the lower electrode 345 via the contact 61 etc.

An insulating layer 349 is formed over the entire surface including an area above the capacitor structure CS. The common potential line 63 and the island-shaped relay wire 63A are formed on the insulating layer 349. The relay wire 63A is formed in the same layer as the common potential line 63. A contact 362 in FIG. 32B is disposed to connect the common potential line 63 to the upper electrode 347 of the capacitor structure CS, and is formed so as to be in contact with the conductive material 348 that is embedded in the recess portion in the upper electrode 347. The common potential V_{com} is applied to the upper electrode 347 via the conductive material 348.

The insulating film 64 is formed over the entire surface including an area above the common potential line 63 and the relay wire 63A. The relay wire 72 is formed on the insulating film 64. The relay wire 72 is connected to the lower electrode 345 via the relay electrode 343 so that a pixel voltage held by the capacitor structure CS is applied.

Also in this configuration, contacts from a lower layer are reduced. Consequently, the plan layout of the capacitor structure CS can be increased.

### Explanation Of Electronic Apparatus

The liquid crystal display device according to the present disclosure having been explained so far can be used as a display section (display device) of an electronic apparatus belonging to any field for displaying an image or video of a video signal inputted to the electronic apparatus or a video signal generated in the electronic apparatus. For example, the liquid crystal display device according to the present disclosure can be used as a display section of a television set, a digital still camera, a notebook-type personal computer, a mobile terminal apparatus such as a mobile phone, a video camera, or a head mounted display.

Examples of the liquid crystal display device according to the present disclosure include a device having a sealed module shape. One of the examples is a display module that is formed by attaching a counter portion made from a glass material or the like to a pixel array section. It is to be noted that a circuit section or a flexible printed circuit (FPC) to/from which a signal etc. from the outside to the pixel array section is inputted/outputted may be provided to the display module. As specific examples of an electronic apparatus using the liquid crystal display device according to the present disclosure, a projection type display apparatus, a digital still camera, and a head mounted display, are explained below. However, these apparatuses are some of the specific examples. Thus, the electronic apparatus using the liquid crystal display device according to the present disclosure is not limited to these examples.

### SPECIFIC EXAMPLE 1

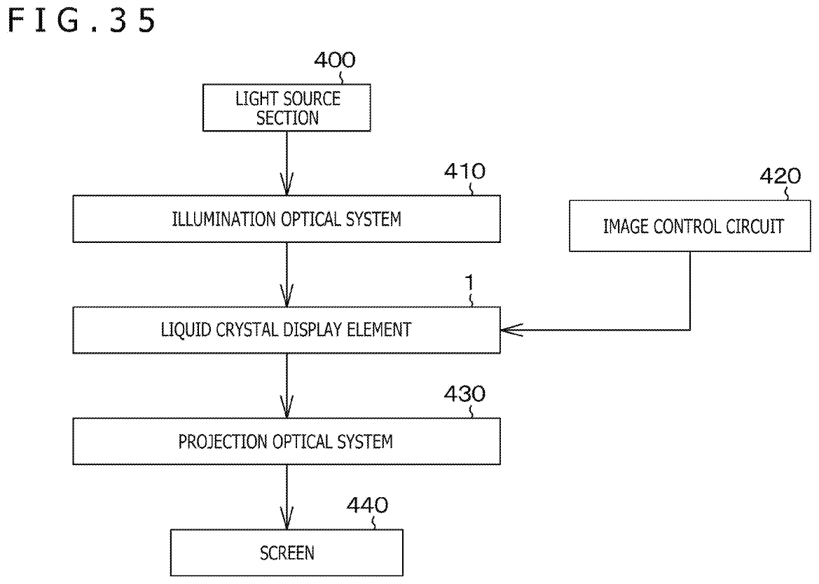

FIG. 35 is a conceptual diagram of a projection-type display apparatus using the liquid crystal display device according to the present disclosure. The projection-type display apparatus includes a light source section 400, an illumination optical system 410, the liquid crystal display device 1, an image control circuit 420 for driving the liquid crystal display device, a projection optical system 430, a screen 440, etc. The light source section 400 can include any lamp such as a xenon lamp, and a semiconductor light emitting element such as a light emitting diode, for example. The illumination optical system 410 is used to guide light from the light source section 400 to the liquid crystal display device 1, and includes an optical element such as a prism or a dichroic mirror. The liquid crystal display device 1 operates as a light valve. An image is projected to the screen 440 via the projection optical system 430.

### SPECIFIC EXAMPLE 2

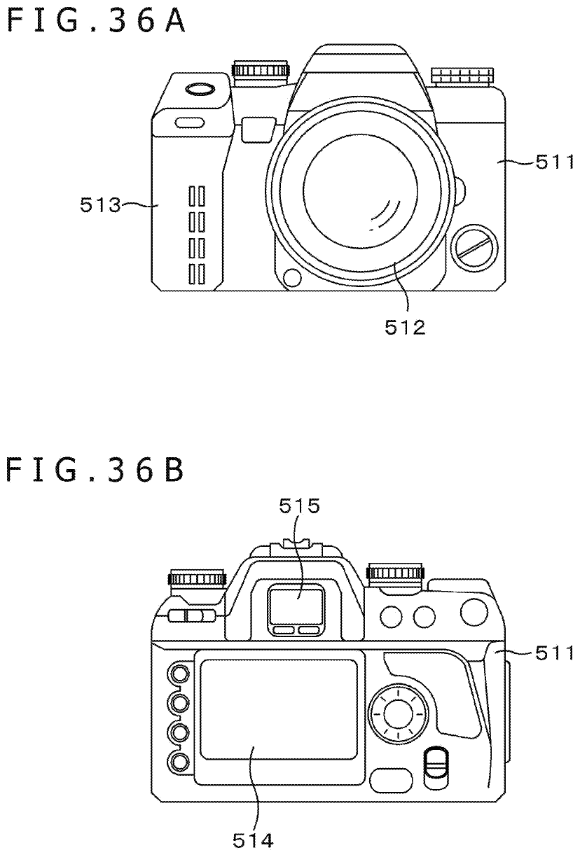

FIG. 36 is a diagram illustrating an external appearance of a lens interchangeable single-lens reflex type digital still camera. FIG. 36A is a front view of the camera. FIG. 36B is a rear view of the camera. For example, in the lens interchangeable single-lens reflex type digital still camera, an interchangeable photographing lens unit (interchangeable lens) 512 is disposed on the front right side of a camera body section (camera body) 511, and a grip section 513 to be gripped by a photographer is disposed on the front left side.

Further, a monitor 514 is provided at a substantially center of the rear surface of the camera body section 511. A viewfinder (ocular window) 515 is provided above the monitor 514. By looking into the viewfinder 515, a photographer can decide a picture composition while visually recognizing a light image of a subject guided from the photographing lens unit 512.

In the lens interchangeable single-lens reflex type digital still camera having the above configuration, the liquid crystal display device according to the present disclosure can be used as the viewfinder 515. That is, the liquid crystal display device according to the present disclosure is used as the viewfinder 515, whereby the lens interchangeable single-lens reflex type digital still camera according to the present embodiment can be produced.

### SPECIFIC EXAMPLE 3

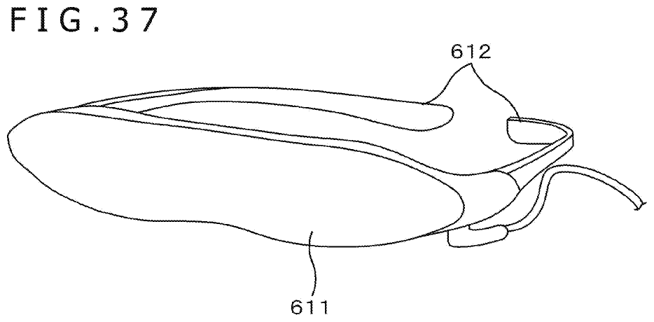

FIG. 37 is a diagram illustrating an external appearance of a head mounted display. For example, in the head mounted display, ear hook sections 612 to be mounted on the head portion of a user are provided at both ends of an eyeglass-shaped display section 611. The liquid crystal display device according to the present disclosure can be used as the display section 611 of this head mounted display. That is, the liquid crystal display device according to the present disclosure is used as the display section 611, whereby the head mounted display according to the present embodiment can be produced.

### SPECIFIC EXAMPLE 4

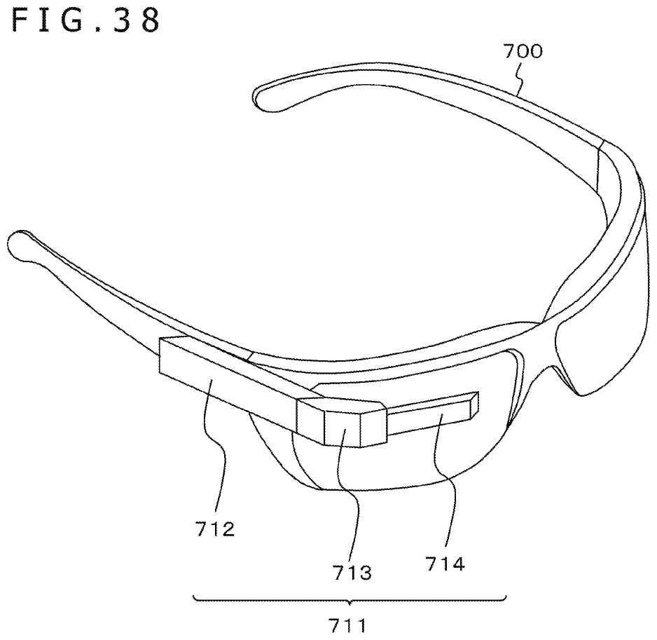

FIG. 38 is a diagram illustrating an external appearance of a see-through head mounted display. The see-through head mounted display 711 includes a body section 712, an arm 713, and a barrel 714.

The body section 712 is connected to the arm 713 and a pair of eyeglasses 700. Specifically, an end, in the long-side direction, of the body section 712 is connected to the arm 713, and one side of a side surface of the body section 712 is connected to the pair of eyeglasses 700 via a connection member. It is to be noted that the body section 712 may be mounted directly on the head of a human body.

The body section 712 includes a built-in control substrate for controlling operation of the see-through head mounted display 711, and a built-in display section. The arm 713 supports the barrel 714 by connecting the body section 712 to the barrel 714. Specifically, the arm 713 is connected to both an end of the body section 712 and an end of the barrel 714 so that the barrel 714 is fixed. In addition, the arm 713 includes a built-in signal line for communicating data concerning an image to be provided from the body section 712 to the barrel 714.

Through an eyepiece lens, the barrel 714 projects image light which is provided from the body section 712 through the arm 713, to eyes of a user who is wearing the see-through head mounted display 711. The liquid crystal display device according to the present disclosure can be used as a display section of the body section 712 of the see-through head mounted display 711.

### APPLICATION EXAMPLES

The technology according to the present disclosure is applicable to various products. For example, the technology according to the present disclosure may be implemented by a device that is mounted on any one of various mobile bodies including automobiles, electric vehicles, hybrid electric vehicles, motorcycles, bicycles, personal mobilities, aircrafts, drones, ships, robots, construction machines, and agricultural machines (tractors).

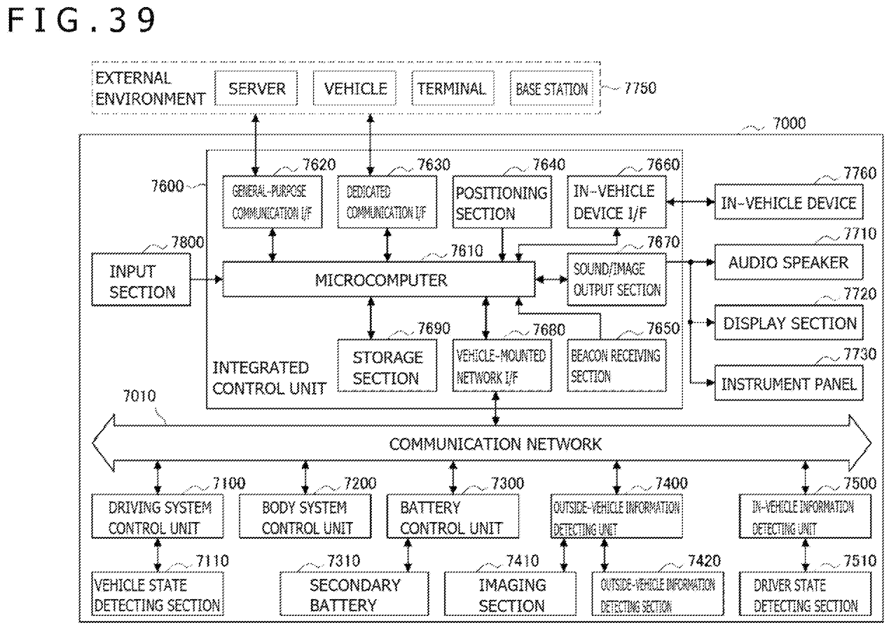

FIG. 39 is a block diagram depicting an example of schematic configuration of a vehicle control system 7000 as an example of a mobile body control system to which the technology according to an embodiment of the present disclosure can be applied. The vehicle control system 7000 includes a plurality of electronic control units connected to each other via a communication network 7010. In the example depicted in FIG. 39, the vehicle control system 7000 includes a driving system control unit 7100, a body system control unit 7200, a battery control unit 7300, an outside-vehicle information detecting unit 7400, an in-vehicle information detecting unit 7500, and an integrated control unit 7600. The communication network 7010 connecting the plurality of control units to each other may, for example, be a vehicle-mounted communication network compliant with an arbitrary standard such as controller area network (CAN), local interconnect network (LIN), local area network (LAN), FlexRay (registered trademark), or the like.

Each of the control units includes: a microcomputer that performs arithmetic processing according to various kinds of programs; a storage section that stores the programs executed by the microcomputer, parameters used for various kinds of operations, or the like; and a driving circuit that drives various kinds of control target devices. Each of the control units further includes: a network interface (I/F) for performing communication with other control units via the communication network 7010; and a communication I/F for performing communication with a device, a sensor, or the like within and without the vehicle by wire communication or radio communication. A functional configuration of the integrated control unit 7600 illustrated in FIG. 39 includes a microcomputer 7610, a general-purpose communication I/F 7620, a dedicated communication I/F 7630, a positioning section 7640, a beacon receiving section 7650, an in-vehicle device I/F 7660, a sound/image output section 7670, a vehicle-mounted network I/F 7680, and a storage section 7690. The other control units similarly include a microcomputer, a communication I/F, a storage section, and the like.

The driving system control unit 7100 controls the operation of devices related to the driving system of the vehicle in accordance with various kinds of programs. For example, the driving system control unit 7100 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like. The driving system control unit 7100 may have a function as a control device of an antilock brake system (ABS), electronic stability control (ESC), or the like.

The driving system control unit 7100 is connected with a vehicle state detecting section 7110. The vehicle state detecting section 7110, for example, includes at least one of a gyro sensor that detects the angular velocity of axial rotational movement of a vehicle body, an acceleration sensor that detects the acceleration of the vehicle, and sensors for detecting an amount of operation of an accelerator pedal, an amount of operation of a brake pedal, the steering angle of a steering wheel, an engine speed or the rotational speed of wheels, and the like. The driving system control unit 7100 performs arithmetic processing using a signal input from the vehicle state detecting section 7110, and controls the internal combustion engine, the driving motor, an electric power steering device, the brake device, and the like.

The body system control unit 7200 controls the operation of various kinds of devices provided to the vehicle body in accordance with various kinds of programs. For example, the body system control unit 7200 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 7200. The body system control unit 7200 receives these input radio waves or signals, and controls a door lock device, the power window device, the lamps, or the like of the vehicle.

The battery control unit 7300 controls a secondary battery 7310, which is a power supply source for the driving motor, in accordance with various kinds of programs. For example, the battery control unit 7300 is supplied with information about a battery temperature, a battery output voltage, an amount of charge remaining in the battery, or the like from a battery device including the secondary battery 7310. The battery control unit 7300 performs arithmetic processing using these signals, and performs control for regulating the temperature of the secondary battery 7310 or controls a cooling device provided to the battery device or the like.

The outside-vehicle information detecting unit 7400 detects information about the outside of the vehicle including the vehicle control system 7000. For example, the outside-vehicle information detecting unit 7400 is connected with at least one of an imaging section 7410 and an outside-vehicle information detecting section 7420. The imaging section 7410 includes at least one of a time-of-flight (ToF) camera, a stereo camera, a monocular camera, an infrared camera, and other cameras. The outside-vehicle information detecting section 7420, for example, includes at least one of an environmental sensor for detecting current atmospheric conditions or weather conditions and a peripheral information detecting sensor for detecting another vehicle, an obstacle, a pedestrian, or the like on the periphery of the vehicle including the vehicle control system 7000.

The environmental sensor, for example, may be at least one of a rain drop sensor detecting rain, a fog sensor detecting a fog, a sunshine sensor detecting a degree of sunshine, and a snow sensor detecting a snowfall. The peripheral information detecting sensor may be at least one of an ultrasonic sensor, a radar device, and a LIDAR device (Light detection and Ranging device, or Laser imaging detection and ranging device). Each of the imaging section 7410 and the outside-vehicle information detecting section 7420 may be provided as an independent sensor or device, or may be provided as a device in which a plurality of sensors or devices are integrated.

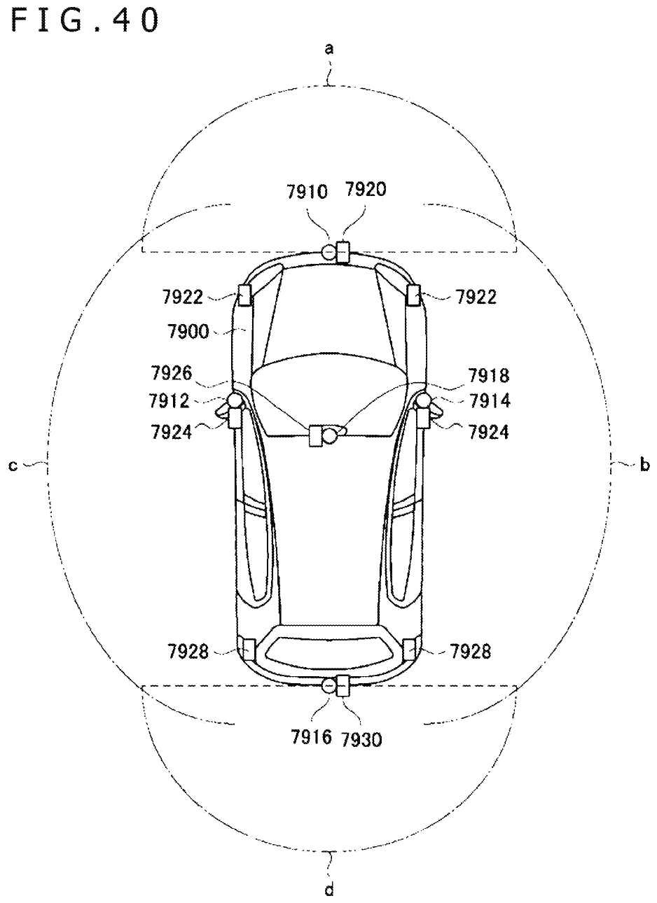

FIG. 40 depicts an example of installation positions of the imaging section 7410 and the outside-vehicle information detecting section 7420. Imaging sections 7910, 7912, 7914, 7916, and 7918 are, for example, disposed at at least one of positions on a front nose, sideview mirrors, a rear bumper, and a back door of the vehicle 7900 and a position on an upper portion of a windshield within the interior of the vehicle. The imaging section 7910 provided to the front nose and the imaging section 7918 provided to the upper portion of the windshield within the interior of the vehicle obtain mainly an image of the front of the vehicle 7900. The imaging sections 7912 and 7914 provided to the sideview mirrors obtain mainly an image of the sides of the vehicle 7900. The imaging section 7916 provided to the rear bumper or the back door obtains mainly an image of the rear of the vehicle 7900. The imaging section 7918 provided to the upper portion of the windshield within the interior of the vehicle is used mainly to detect a preceding vehicle, a pedestrian, an obstacle, a signal, a traffic sign, a lane, or the like.

Incidentally, FIG. 40 depicts an example of photographing ranges of the respective imaging sections 7910, 7912, 7914, and 7916. An imaging range a represents the imaging range of the imaging section 7910 provided to the front nose. Imaging ranges b and c respectively represent the imaging ranges of the imaging sections 7912 and 7914 provided to the sideview mirrors. An imaging range d represents the imaging range of the imaging section 7916 provided to the rear bumper or the back door. A bird's-eye image of the vehicle 7900 as viewed from above can be obtained by superimposing image data imaged by the imaging sections 7910, 7912, 7914, and 7916, for example.

Outside-vehicle information detecting sections 7920, 7922, 7924, 7926, 7928, and 7930 provided to the front, rear, sides, and corners of the vehicle 7900 and the upper portion of the windshield within the interior of the vehicle may be, for example, an ultrasonic sensor or a radar device. The outside-vehicle information detecting sections 7920, 7926, and 7930 provided to the front nose of the vehicle 7900, the rear bumper, the back door of the vehicle 7900, and the upper portion of the windshield within the interior of the vehicle may be a LIDAR device, for example. These outside-vehicle information detecting sections 7920 to 7930 are used mainly to detect a preceding vehicle, a pedestrian, an obstacle, or the like.

Returning to FIG. 39, the description will be continued. The outside-vehicle information detecting unit 7400 makes the imaging section 7410 image an image of the outside of the vehicle, and receives imaged image data. In addition, the outside-vehicle information detecting unit 7400 receives detection information from the outside-vehicle information detecting section 7420 connected to the outside-vehicle information detecting unit 7400. In a case where the outside-vehicle information detecting section 7420 is an ultrasonic sensor, a radar device, or a LIDAR device, the outside-vehicle information detecting unit 7400 transmits an ultrasonic wave, an electromagnetic wave, or the like, and receives information of a received reflected wave. On the basis of the received information, the outside-vehicle information detecting unit 7400 may perform processing of detecting an object such as a human, a vehicle, an obstacle, a sign, a character on a road surface, or the like, or processing of detecting a distance thereto. The outside-vehicle information detecting unit 7400 may perform environment recognition processing of recognizing a rainfall, a fog, road surface conditions, or the like on the basis of the received information. The outside-vehicle information detecting unit 7400 may calculate a distance to an object outside the vehicle on the basis of the received information.

In addition, on the basis of the received image data, the outside-vehicle information detecting unit 7400 may perform image recognition processing of recognizing a human, a vehicle, an obstacle, a sign, a character on a road surface, or the like, or processing of detecting a distance thereto. The outside-vehicle information detecting unit 7400 may subject the received image data to processing such as distortion correction, alignment, or the like, and combine the image data imaged by a plurality of different imaging sections 7410 to generate a bird's-eye image or a panoramic image. The outside-vehicle information detecting unit 7400 may perform viewpoint conversion processing using the image data imaged by the imaging section 7410 including the different imaging parts.

The in-vehicle information detecting unit 7500 detects information about the inside of the vehicle. The in-vehicle information detecting unit 7500 is, for example, connected with a driver state detecting section 7510 that detects the state of a driver. The driver state detecting section 7510 may include a camera that images the driver, a biosensor that detects biological information of the driver, a microphone that collects sound within the interior of the vehicle, or the like. The biosensor is, for example, disposed in a seat surface, the steering wheel, or the like, and detects biological information of an occupant sitting in a seat or the driver holding the steering wheel. On the basis of detection information input from the driver state detecting section 7510, the in-vehicle information detecting unit 7500 may calculate a degree of fatigue of the driver or a degree of concentration of the driver, or may determine whether the driver is dozing. The in-vehicle information detecting unit 7500 may subject an audio signal obtained by the collection of the sound to processing such as noise canceling processing or the like.

The integrated control unit 7600 controls general operation within the vehicle control system 7000 in accordance with various kinds of programs. The integrated control unit 7600 is connected with an input section 7800. The input section 7800 is implemented by a device capable of input operation by an occupant, such, for example, as a touch panel, a button, a microphone, a switch, a lever, or the like. The integrated control unit 7600 may be supplied with data obtained by voice recognition of voice input through the microphone. The input section 7800 may, for example, be a remote control device using infrared rays or other radio waves, or an external connecting device such as a mobile telephone, a personal digital assistant (PDA), or the like that supports operation of the vehicle control system 7000. The input section 7800 may be, for example, a camera. In that case, an occupant can input information by gesture. Alternatively, data may be input which is obtained by detecting the movement of a wearable device that an occupant wears. Further, the input section 7800 may, for example, include an input control circuit or the like that generates an input signal on the basis of information input by an occupant or the like using the above-described input section 7800, and which outputs the generated input signal to the integrated control unit 7600. An occupant or the like inputs various kinds of data or gives an instruction for processing operation to the vehicle control system 7000 by operating the input section 7800.

The storage section 7690 may include a read only memory (ROM) that stores various kinds of programs executed by the microcomputer and a random access memory (RAM) that stores various kinds of parameters, operation results, sensor values, or the like. In addition, the storage section 7690 may be implemented by a magnetic storage device such as a hard disc drive (HDD) or the like, a semiconductor storage device, an optical storage device, a magneto-optical storage device, or the like.

The general-purpose communication I/F 7620 is a communication I/F used widely, which communication I/F mediates communication with various apparatuses present in an external environment 7750. The general-purpose communication I/F 7620 may implement a cellular communication protocol such as global system for mobile communications (GSM (registered trademark)), worldwide interoperability for microwave access (WiMAX (registered trademark)), long term evolution (LTE (registered trademark)), LTE-advanced (LTE-A), or the like, or another wireless communication protocol such as wireless LAN (referred to also as wireless fidelity (Wi-Fi (registered trademark)), Bluetooth (registered trademark), or the like. The general-purpose communication I/F 7620 may, for example, connect to an apparatus (for example, an application server or a control server) present on an external network (for example, the Internet, a cloud network, or a company-specific network) via a base station or an access point. In addition, the general-purpose communication I/F 7620 may connect to a terminal present in the vicinity of the vehicle (which terminal is, for example, a terminal of the driver, a pedestrian, or a store, or a machine type communication (MTC) terminal) using a peer to peer (P2P) technology, for example.

The dedicated communication I/F 7630 is a communication I/F that supports a communication protocol developed for use in vehicles. The dedicated communication I/F 7630 may implement a standard protocol such, for example, as wireless access in vehicle environment (WAVE), which is a combination of institute of electrical and electronic engineers (IEEE) 802.11p as a lower layer and IEEE 1609 as a higher layer, dedicated short range communications (DSRC), or a cellular communication protocol. The dedicated communication I/F 7630 typically carries out V2X communication as a concept including one or more of communication between a vehicle and a vehicle (Vehicle to Vehicle), communication between a road and a vehicle (Vehicle to Infrastructure), communication between a vehicle and a home (Vehicle to Home), and communication between a pedestrian and a vehicle (Vehicle to Pedestrian).

The positioning section 7640, for example, performs positioning by receiving a global navigation satellite system (GNSS) signal from a GNSS satellite (for example, a GPS signal from a global positioning system (GPS) satellite), and generates positional information including the latitude, longitude, and altitude of the vehicle. Incidentally, the positioning section 7640 may identify a current position by exchanging signals with a wireless access point, or may obtain the positional information from a terminal such as a mobile telephone, a personal handyphone system (PHS), or a smart phone that has a positioning function.

The beacon receiving section 7650, for example, receives a radio wave or an electromagnetic wave transmitted from a radio station installed on a road or the like, and thereby obtains information about the current position, congestion, a closed road, a necessary time, or the like. Incidentally, the function of the beacon receiving section 7650 may be included in the dedicated communication I/F 7630 described above.

The in-vehicle device I/F 7660 is a communication interface that mediates connection between the microcomputer 7610 and various in-vehicle devices 7760 present within the vehicle. The in-vehicle device I/F 7660 may establish wireless connection using a wireless communication protocol such as wireless LAN, Bluetooth (registered trademark), near field communication (NFC), or wireless universal serial bus (WUSB). In addition, the in-vehicle device I/F 7660 may establish wired connection by universal serial bus (USB), high-definition multimedia interface (HDMI (registered trademark)), mobile high-definition link (MHL), or the like via a connection terminal (and a cable if necessary) not depicted in the figures. The in-vehicle devices 7760 may, for example, include at least one of a mobile device and a wearable device possessed by an occupant and an information device carried into or attached to the vehicle. The in-vehicle devices 7760 may also include a navigation device that searches for a path to an arbitrary destination. The in-vehicle device I/F 7660 exchanges control signals or data signals with these in-vehicle devices 7760.

The vehicle-mounted network I/F 7680 is an interface that mediates communication between the microcomputer 7610 and the communication network 7010. The vehicle-mounted network I/F 7680 transmits and receives signals or the like in conformity with a predetermined protocol supported by the communication network 7010.

The microcomputer 7610 of the integrated control unit 7600 controls the vehicle control system 7000 in accordance with various kinds of programs on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. For example, the microcomputer 7610 may calculate a control target value for the driving force generating device, the steering mechanism, or the braking device on the basis of the obtained information about the inside and outside of the vehicle, and output a control command to the driving system control unit 7100. For example, the microcomputer 7610 may perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like. In addition, the microcomputer 7610 may perform cooperative control intended for automatic driving, which makes the vehicle to travel autonomously without depending on the operation of the driver, or the like, by controlling the driving force generating device, the steering mechanism, the braking device, or the like on the basis of the obtained information about the surroundings of the vehicle.

The microcomputer 7610 may generate three-dimensional distance information between the vehicle and an object such as a surrounding structure, a person, or the like, and generate local map information including information about the surroundings of the current position of the vehicle, on the basis of information obtained via at least one of the general-purpose communication I/F 7620, the dedicated communication I/F 7630, the positioning section 7640, the beacon receiving section 7650, the in-vehicle device I/F 7660, and the vehicle-mounted network I/F 7680. In addition, the microcomputer 7610 may predict danger such as collision of the vehicle, approaching of a pedestrian or the like, an entry to a closed road, or the like on the basis of the obtained information, and generate a warning signal. The warning signal may, for example, be a signal for producing a warning sound or lighting a warning lamp.

The sound/image output section 7670 transmits an output signal of at least one of a sound and an image to an output device capable of visually or auditorily notifying information to an occupant of the vehicle or the outside of the vehicle. In the example of FIG. 39, an audio speaker 7710, a display section 7720, and an instrument panel 7730 are illustrated as the output device. The display section 7720 may, for example, include at least one of an on-board display and a head-up display. The display section 7720 may have an augmented reality (AR) display function. The output device may be other than these devices, and may be another device such as headphones, a wearable device such as an eyeglass type display worn by an occupant or the like, a projector, a lamp, or the like. In a case where the output device is a display device, the display device visually displays results obtained by various kinds of processing performed by the microcomputer 7610 or information received from another control unit in various forms such as text, an image, a table, a graph, or the like. In addition, in a case where the output device is an audio output device, the audio output device converts an audio signal constituted of reproduced audio data or sound data or the like into an analog signal, and auditorily outputs the analog signal.

Incidentally, at least two control units connected to each other via the communication network 7010 in the example depicted in FIG. 39 may be integrated into one control unit. Alternatively, each individual control unit may include a plurality of control units. Further, the vehicle control system 7000 may include another control unit not depicted in the figures. In addition, part or the whole of the functions performed by one of the control units in the above description may be assigned to another control unit. That is, predetermined arithmetic processing may be performed by any of the control units as long as information is transmitted and received via the communication network 7010. Similarly, a sensor or a device connected to one of the control units may be connected to another control unit, and a plurality of control units may mutually transmit and receive detection information via the communication network 7010.

The technology according to the present disclosure is applicable to the aforementioned display section of the output device that is capable of visually or auditorily notifying information, for example.

### Others

It is to be noted that the technology according to the present disclosure can have the following configurations.

### [A1]

A transistor array substrate including:

a capacitor structure and a transistor formed on a support substrate, in which

the capacitor structure includes
a relay electrode,
a lower electrode that has a bottom surface disposed on the relay electrode and has a wall surface extending obliquely with respect to the bottom surface,
a dielectric film that is formed on the lower electrode, and
an upper electrode that is formed on the dielectric film,

the dielectric film and the upper electrode are formed in accordance with the lower electrode, and

a conductive material is embedded in a recess portion in the upper electrode.

### [A2]

The transistor array substrate according to [A1], in which

a wiring layer is formed above the capacitor structure, and

a contact between the upper electrode of the capacitor structure and the wiring layer is formed so as to be in contact with the conductive material that is embedded in the recess portion in the upper electrode.

### [A3]

The transistor array substrate according to [A1] or [A2], in which

the lower electrode, the dielectric film, and the upper electrode are formed in an opening portion that is disposed in an interlayer insulating film, and

an upper surface of the capacitor structure is flattened in accordance with an upper surface of the interlayer insulating film.

### [A4]

The transistor array substrate according to [A3], in which

respective end surfaces, on an upper surface of the capacitor structure, of the lower electrode, the dielectric film, and the upper electrode are flattened in accordance with the upper surface of the interlayer insulating film.

### [A5]

The transistor array substrate according to [A3], in which

an end surface, on the upper surface of the capacitor structure, of the dielectric film is inwardly recessed from respective end surfaces of the lower electrode and the upper electrode.

### [A6]

The transistor array substrate according to [A1], in which

the lower electrode is formed in an opening portion that is disposed in an interlayer insulating film, and

an end surface of the lower electrode is flattened in accordance with an upper surface of the interlayer insulating film, and

the dielectric film is formed so as to coat the end surface of the lower electrode and an interlayer insulating film region around the end surface of the lower electrode.

### [A7]

The transistor array substrate according to any one of [A1] to [A6], in which

the lower electrode has a plurality of bottom surfaces.

### [A8]

The transistor array substrate according to any one of [A1] to [A7], in which

the capacitor structure is disposed between the transistor and the wiring layer.

### [A9]

The transistor array substrate according to any one of [A1] to [A7], in which

the transistor array substrate includes a plurality of wiring layers, and

the capacitor structure is disposed between the wiring layers.

### [A10]

The transistor array substrate according to any one of [A1] to [A9], further including:

a pixel electrode to which a pixel voltage held by the capacitor structure is applied.

### [A11]

The transistor array substrate according to any one of [A1] to [A10], in which

the transistor is disposed above a scan line that is disposed on the support substrate, and

a periphery of the transistor is enclosed with a wall-shaped lateral light shielding film extending in a direction that is normal to the support substrate.

### [A12]

The transistor array substrate according to [A11], in which

the lateral light shielding film is formed along an edge of the scan line.

### [B1]

A transistor array substrate production method including a step of forming a capacitor structure on a support substrate, the method including:

a step of providing a relay electrode on an insulating layer, forming an interlayer insulating film over an entire surface, and then, forming an opening portion in the interlayer insulating film in such a way that the opening portion has a bottom portion from which the relay electrode is exposed, and has a wall surface extending obliquely with respect to the bottom portion;

a step of subsequently forming a first conductive material layer to form a lower electrode, an insulating material layer to form a dielectric film, and a second conductive material layer to form an upper electrode sequentially over an entire surface including an inner side of the opening portion;

a step of subsequently forming a third conductive material layer over an entire surface including an area above the upper electrode; and

a step of subsequently performing, on an entire surface, a flattening process so as to expose the interlayer insulating film.

### [B2]

The transistor array substrate production method according to [B1], further including:

a step of etching an end of the dielectric film after the flattening process is performed.

### [B3]

The transistor array substrate production method according to [B1] or [B2], in which

a contact between the upper electrode of the capacitor structure and a wiring layer disposed above the capacitor structure is formed so as to be in contact with the conductive material that is embedded in a recess portion in the upper electrode.

### [C1]

A transistor array substrate production method including a step of forming a capacitor structure on a support substrate, the method including:

a step of providing a relay electrode on an insulating layer, forming an interlayer insulating film over an entire surface, and then, forming an opening portion in the interlayer insulating film in such a way that the opening portion has a bottom portion from which the relay electrode is exposed, and has a wall surface extending obliquely with respect to the bottom portion;

a step of subsequently forming a first conductive material layer to form a lower electrode, over an entire surface including an inner side of the opening portion;

a step of subsequently performing, on an entire surface, a flattening process so as to expose the interlayer insulating film; and

a step of subsequently forming a dielectric film that coats an end surface of the lower electrode and an interlayer insulating film region around the end surface of the lower electrode, an upper electrode that is disposed on the dielectric film, and a conductive material that is embedded in a recess portion in the upper electrode.

### [C2]

The transistor array substrate production method according to [C1], in which

a contact between the upper electrode of the capacitor structure and a wiring layer disposed above the capacitor structure is formed so as to be in contact with the conductive material that is embedded in the recess portion in the upper electrode.

### [D1]

A capacitor structure including:

a relay electrode;

a lower electrode that has a bottom surface disposed on the relay electrode and has a wall surface extending obliquely with respect to the bottom surface,

a dielectric film that is formed on the lower electrode; and

an upper electrode that is formed on the dielectric film, in which

the dielectric film and the upper electrode are formed in accordance with the lower electrode, and

a conductive material is embedded in a recess portion in the upper electrode.

### [D2]

The capacitor structure according to [D1], in which

a wiring layer is formed above the capacitor structure, and

a contact between the upper electrode of the capacitor structure and the wiring layer is formed so as to be in contact with the conductive material that is embedded in the recess portion in the upper electrode.

### [D3]

The capacitor structure according to [D1] or [D2], in which

the lower electrode, the dielectric film, and the upper electrode are formed in an opening portion that is disposed in an interlayer insulating film, and

an upper surface of the capacitor structure is flattened in accordance with an upper surface of the interlayer insulating film.

### [D4]

The capacitor structure according to [D3], in which

respective end surfaces, on an upper surface of the capacitor structure, of the lower electrode, the dielectric film, and the upper electrode are flattened in accordance with the upper surface of the interlayer insulating film.

### [D5]

The capacitor structure according to [D3], in which

an end surface, on the upper surface of the capacitor structure, of the dielectric film is inwardly recessed from respective end surfaces of the lower electrode and the upper electrode.

### [D6]

The capacitor structure according to [D1], in which

the lower electrode is formed in an opening portion that is disposed in an interlayer insulating film, and

an end surface of the lower electrode is flattened in accordance with an upper surface of the interlayer insulating film, and

the dielectric film is formed so as to coat the end surface of the lower electrode and an interlayer insulating film region around the end surface of the lower electrode.

### [D7]

The capacitor structure according to any one of [D1] to [D6], in which

the lower electrode has a plurality of bottom surfaces.

### [E1]

A liquid crystal display device including:

a transistor array substrate;

a counter substrate that is opposed to the transistor array substrate; and

a liquid crystal material layer that is sealed between the transistor array substrate and the counter substrate, in which

the transistor array substrate includes a capacitor structure and a transistor formed on a support substrate,

the capacitor structure includes
a relay electrode,
a lower electrode that has a bottom surface disposed on the relay electrode and has a wall surface extending obliquely with respect to the bottom surface,
a dielectric film that is formed on the lower electrode, and
an upper electrode that is formed on the dielectric film,

the dielectric film and the upper electrode are formed in accordance with the lower electrode, and

a conductive material is embedded in a recess portion in the upper electrode.

### [E2]

The liquid crystal display device according to [E1], in which

a wiring layer is formed above the capacitor structure, and

a contact between the upper electrode of the capacitor structure and the wiring layer is formed so as to be in contact with the conductive material that is embedded in the recess portion in the upper electrode.

### [E3]

The liquid crystal display device according to [E1] or [E2], in which

the lower electrode, the dielectric film, and the upper electrode are formed in an opening portion that is disposed in an interlayer insulating film, and

an upper surface of the capacitor structure is flattened in accordance with an upper surface of the interlayer insulating film.

### [E4]

The liquid crystal display device according to [E3], in which

respective end surfaces, on an upper surface of the capacitor structure, of the lower electrode, the dielectric film, and the upper electrode are flattened in accordance with the upper surface of the interlayer insulating film.

### [E5]

The liquid crystal display device according to [E3], in which

an end surface, on the upper surface of the capacitor structure, of the dielectric film is inwardly recessed from respective end surfaces of the lower electrode and the upper electrode.

### [E6]

The liquid crystal display device according to [E1], in which

the lower electrode is formed in an opening portion that is disposed in an interlayer insulating film, and

an end surface of the lower electrode is flattened in accordance with an upper surface of the interlayer insulating film, and

the dielectric film is formed so as to coat the end surface of the lower electrode and an interlayer insulating film region around the end surface of the lower electrode.

### [E7]

The liquid crystal display device according to any one of [E1] to [E6], in which

the lower electrode has a plurality of bottom surfaces.

### [E8]

The liquid crystal display device according to any one of [E1] to [E7], in which

the capacitor structure is disposed between the transistor and the wiring layer.

### [E9]

The liquid crystal display device according to any one of [E1] to [E7], in which

the transistor array substrate includes a plurality of wiring layers, and

the capacitor structure is disposed between the wiring layers.

### [E10]

The liquid crystal display device according to any one of [E1] to [E9], further including:

a pixel electrode to which a pixel voltage held by the capacitor structure is applied.

### [E11]

The liquid crystal display device according to any one of [E1] to [E10], in which

the transistor is disposed above a scan line that is disposed on the support substrate, and

a periphery of the transistor is enclosed with a wall-shaped lateral light shielding film extending in a direction that is normal to the support substrate.

### [E12]

The liquid crystal display device according to [E11], in which

the lateral light shielding film is formed along an edge of the scan line.

### [F1]

An electronic apparatus including:

a liquid crystal display device including
a transistor array substrate,
a counter substrate that is opposed to the transistor array substrate, and
a liquid crystal material layer that is sealed between the transistor array substrate and the counter substrate, in which

the transistor array substrate includes a capacitor structure and a transistor formed on a support substrate,

the capacitor structure includes
a relay electrode,
a lower electrode that has a bottom surface disposed on the relay electrode and has a wall surface extending obliquely with respect to the bottom surface,
a dielectric film that is formed on the lower electrode, and
an upper electrode that is formed on the dielectric film,

the dielectric film and the upper electrode are formed in accordance with the lower electrode, and

a conductive material is embedded in a recess portion in the upper electrode.

### [F2]

The electronic apparatus according to [F1], in which

a wiring layer is formed above the capacitor structure, and

a contact between the upper electrode of the capacitor structure and the wiring layer is formed so as to be in contact with the conductive material that is embedded in the recess portion in the upper electrode.

### [F3]

The electronic apparatus according to [F1] or [F2], in which

the lower electrode, the dielectric film, and the upper electrode are formed in an opening portion that is disposed in an interlayer insulating film, and

an upper surface of the capacitor structure is flattened in accordance with an upper surface of the interlayer insulating film.

### [F4]

The electronic apparatus according to [F3], in which

respective end surfaces, on an upper surface of the capacitor structure, of the lower electrode, the dielectric film, and the upper electrode are flattened in accordance with the upper surface of the interlayer insulating film.

### [F5]

The electronic apparatus according to [F3], in which

an end surface, on the upper surface of the capacitor structure, of the dielectric film is inwardly recessed from respective end surfaces of the lower electrode and the upper electrode.

### [F6]

The electronic apparatus according to [F1], in which

the lower electrode is formed in an opening portion that is disposed in an interlayer insulating film, and

an end surface of the lower electrode is flattened in accordance with an upper surface of the interlayer insulating film, and

the dielectric film is formed so as to coat the end surface of the lower electrode and an interlayer insulating film region around the end surface of the lower electrode.

### [F7]

The electronic apparatus according to any one of [F1] to [F6], in which

the lower electrode has a plurality of bottom surfaces.

### [F8]

The electronic apparatus according to any one of [F1] to [F7], in which

the capacitor structure is disposed between the transistor and the wiring layer.

### [F9]

The electronic apparatus according to any one of [F1] to [F7], in which

the transistor array substrate includes a plurality of wiring layers, and

the capacitor structure is disposed between the wiring layers.

### [F10]

The electronic apparatus according to any one of [F1] to [F9], further including:

a pixel electrode to which a pixel voltage held by the capacitor structure is applied.

### [F11]

The electronic apparatus according to any one of [F1] to [F10], in which

the transistor is disposed above a scan line that is disposed on the support substrate, and

a periphery of the transistor is enclosed with a wall-shaped lateral light shielding film extending in a direction that is normal to the support substrate.

### [F12]

The electronic apparatus according to [F11], in which

the lateral light shielding film is formed along an edge of the scan line.

### REFERENCE SIGNS LIST

1: Liquid crystal display device

10: Support substrate

11: Scan line

11A: Lateral light shielding film

12: Insulating film

21: Semiconductor material layer

22: Gate insulating film

31: Contact

32: Gate electrode

33: Insulating film

41: Contact

42: Contact

43: Relay electrode

43A: Relay wire

44: Interlayer insulating film

45: Lower electrode

46: Dielectric film

47: Upper electrode

48: Conductive material

48A: Third conductive material layer

49: Insulating layer

51: Contact

52: Contact

53: Contact

54: Signal line

54A, 54B: Relay wire

55: Insulating film

61: Contact

62: Contact

63: Common potential line

63A: Relay wire

64: Insulating film

71: Contact

72: Relay wire

73: Flattened film

81: Pixel electrode

82: Contact

99: Sacrificial layer

100, 100A, 100B, 100C, 100D, 100E, 100F, 100G: Transistor array substrate

101: Horizontal drive circuit

102: Vertical drive circuit

110: Liquid crystal material layer

111: Seal section

120: Counter substrate

243: Relay electrode

243A: Relay wire

244: Interlayer insulating film

245: Lower electrode

246: Dielectric film

247: Upper electrode

248: Conductive material

249: Insulating layer

261: Contact

271: Contact

343: Relay electrode

344: Interlayer insulating film

345: Lower electrode

346: Dielectric film

347: Upper electrode

348: Conductive material

349: Insulating layer

362: Contact

CS: Capacitor structure

TR: Transistor

OP: Opening portion

BT: Bottom portion

WL: Wall portion

400: Light source section

410: Illumination optical system

420: Image control circuit

430: Projection optical system

440: Screen

511: Camera body section

512: Photographing lens unit

513: Grip section

514: Monitor

515: Viewfinder

611: Eyeglass-shaped display section

612: Ear hook section

700: Pair of eyeglasses

711: See-through head mounted display

712: Body section

713: Arm

714: Barrel

1. A transistor array substrate comprising:
a capacitor structure and a transistor formed on a support substrate, wherein
the capacitor structure includes
a relay electrode,
a lower electrode that has a bottom surface disposed on the relay electrode and has a wall surface extending obliquely with respect to the bottom surface,
a dielectric film that is formed on the lower electrode, and
an upper electrode that is formed on the dielectric film,
the dielectric film and the upper electrode are formed in accordance with the lower electrode, and
a conductive material is embedded in a recess portion in the upper electrode.

2. The transistor array substrate according to claim 1, wherein
a wiring layer is formed above the capacitor structure, and
a contact between the upper electrode of the capacitor structure and the wiring layer is formed so as to be in contact with the conductive material that is embedded in the recess portion in the upper electrode.

3. The transistor array substrate according to claim 1, wherein
the lower electrode, the dielectric film, and the upper electrode are formed in an opening portion that is disposed in an interlayer insulating film, and
an upper surface of the capacitor structure is flattened in accordance with an upper surface of the interlayer insulating film.

4. The transistor array substrate according to claim 3, wherein
respective end surfaces, on an upper surface of the capacitor structure, of the lower electrode, the dielectric film, and the upper electrode are flattened in accordance with the upper surface of the interlayer insulating film.

5.
The transistor array substrate according to claim 3, wherein
an end surface, on the upper surface of the capacitor structure, of the dielectric film is inwardly recessed from respective end surfaces of the lower electrode and the upper electrode.

6. The transistor array substrate according to claim 1, wherein
the lower electrode is formed in an opening portion that is disposed in an interlayer insulating film, and
an end surface of the lower electrode is flattened in accordance with an upper surface of the interlayer insulating film, and
the dielectric film is formed so as to coat the end surface of the lower electrode and an interlayer insulating film region around the end surface of the lower electrode.

7. The transistor array substrate according to claim 1, wherein
the lower electrode has a plurality of bottom surfaces.

8. The transistor array substrate according to claim 1, wherein
the capacitor structure is disposed between the transistor and a wiring layer.

9. The transistor array substrate according to claim 1, wherein
the transistor array substrate includes a plurality of wiring layers, and
the capacitor structure is disposed between the wiring layers.

10. The transistor array substrate according to claim 1, further comprising:
a pixel electrode to which a pixel voltage held by the capacitor structure is applied.

11. The transistor array substrate according to claim 1, wherein
the transistor is disposed above a scan line that is disposed on the support substrate, and
a periphery of the transistor is enclosed with a wall-shaped lateral light shielding film extending in a direction that is normal to the support substrate.

12. The transistor array substrate according to claim 11, wherein
the lateral light shielding film is formed along an edge of the scan line.

13. A transistor array substrate production method including a step of forming a capacitor structure on a support substrate, the method comprising:
a step of providing a relay electrode on an insulating layer, forming an interlayer insulating film over an entire surface, and then, forming an opening portion in the interlayer insulating film in such a way that the opening portion has a bottom portion from which the relay electrode is exposed, and has a wall surface extending obliquely with respect to the bottom portion;
a step of subsequently forming a first conductive material layer to form a lower electrode, an insulating material layer to form a dielectric film, and a second conductive material layer to form an upper electrode sequentially over an entire surface including an inner side of the opening portion;
a step of subsequently forming a third conductive material layer over an entire surface including an area above the upper electrode; and
a step of subsequently performing, on an entire surface, a flattening process so as to expose the interlayer insulating film.

14. The transistor array substrate production method according to claim 13, further comprising:
a step of etching an end of the dielectric film after the flattening process is performed.

15. A transistor array substrate production method including a step of forming a capacitor structure on a support substrate, the method comprising:
a step of providing a relay electrode on an insulating layer, forming an interlayer insulating film over an entire surface, and then, forming an opening portion in the interlayer insulating film in such a way that the opening portion has a bottom portion from which the relay electrode is exposed, and has a wall surface extending obliquely with respect to the bottom portion;
a step of subsequently forming a first conductive material layer to form a lower electrode, over an entire surface including an inner side of the opening portion;
a step of subsequently performing, on an entire surface, a flattening process so as to expose the interlayer insulating film; and
a step of subsequently forming a dielectric film that coats an end surface of the lower electrode and an interlayer insulating film region around the end surface of the lower electrode, an upper electrode that is disposed on the dielectric film, and a conductive material that is embedded in a recess portion in the upper electrode.

16. A capacitor structure comprising:
a relay electrode;
a lower electrode that has a bottom surface disposed on the relay electrode and has a wall surface extending obliquely with respect to the bottom surface;
a dielectric film that is formed on the lower electrode; and
an upper electrode that is formed on the dielectric film, wherein
the dielectric film and the upper electrode are formed in accordance with the lower electrode, and
a conductive material is embedded in a recess portion in the upper electrode.

17. A liquid crystal display device comprising:
a transistor array substrate;
a counter substrate that is opposed to the transistor array substrate; and
a liquid crystal material layer that is sealed between the transistor array substrate and the counter substrate, wherein
the transistor array substrate includes a capacitor structure and a transistor formed on a support substrate,
the capacitor structure includes
a relay electrode,
a lower electrode that has a bottom surface disposed on the relay electrode and has a wall surface extending obliquely with respect to the bottom surface,
a dielectric film that is formed on the lower electrode, and
an upper electrode that is formed on the dielectric film,
the dielectric film and the upper electrode are formed in accordance with the lower electrode, and
a conductive material is embedded in a recess portion in the upper electrode.

18. An electronic apparatus comprising:
a liquid crystal display device including
a transistor array substrate,
a counter substrate that is opposed to the transistor array substrate, and
a liquid crystal material layer that is sealed between the transistor array substrate and the counter substrate, wherein
the transistor array substrate includes a capacitor structure and a transistor formed on a support substrate,
the capacitor structure includes
a relay electrode,
a lower electrode that has a bottom surface disposed on the relay electrode and has a wall surface extending obliquely with respect to the bottom surface,
a dielectric film that is formed on the lower electrode, and
an upper electrode that is formed on the dielectric film,
the dielectric film and the upper electrode are formed in accordance with the lower electrode, and
a conductive material is embedded in a recess portion in the upper electrode.
